(19) United States
(12) Patent Application Publication
(10) Pub. No.: US 2024/0145530 A1
(43) Pub. Date: May 2, 2024

(54) INTEGRATED CIRCUIT AND NON-VOLATILE MEMORY DEVICE

(71) Applicant: SAMSUNG ELECTRONICS CO., LTD., Suwon-si (KR)

(72) Inventor: Yongjun KIM, Suwon-si (KR)

(73) Assignee: SAMSUNG ELECTRONICS CO., LTD., Suwon-si (KR)

(21) Appl. No.: 18/221,146

(22) Filed: Jul. 12, 2023

(30) Foreign Application Priority Data
Oct. 27, 2022 (KR) 10-2022-0140561

(51) Int. Cl. H10B 41/27; G11C 16/04; H01L 27/07; H10B 41/35; H10B 43/35; H10B 43/27

(52) U.S. Cl. CPC H01L 28/90; G11C 16/0483; H01L 27/0733; H10B 41/35; H10B 43/35; H10B 41/27; H10B 43/27

(57) ABSTRACT

The present disclosure provides apparatuses including a capacitor structure. In some embodiments, an integrated circuit includes a substrate, and a capacitor structure, disposed above the substrate in a vertical direction, including a first electrode configured to receive a first voltage and including at least one first metal line having a first patterned side surface, a second electrode configured to receive a second voltage and including at least one second metal line having a second patterned side surface, and a dielectric layer disposed between the first electrode and the second electrode. The at least one first metal line and the at least one second metal line extend in a first horizontal direction. The first electrode, the second electrode, and the dielectric layer are disposed on a same layer. The at least one second metal line is spaced apart from the at least one first metal line in a second horizontal direction.

### CROSS-REFERENCE TO RELATED APPLICATIONS

This application claims benefit of priority under 35 U.S.C. § 119 to Korean Patent Application No. 10-2022-0140561, filed on Oct. 27, 2022, in the Korean Intellectual Property Office, the disclosure of which is incorporated by reference herein in its entirety.

### BACKGROUND

### 1. Field

The present disclosure relates to an integrated circuit, and more particularly, to an integrated circuit including a capacitor and a non-volatile memory device including a capacitor.

### 2. Description of Related Art

With the development of semiconductor process technology, high integration of integrated circuits has been accelerating. For example, a metal-insulator-metal (MIM) capacitor, which may include a first electrode, a second electrode, and a dielectric material between the first and second electrodes, may need a structure capable of maintaining desired electrical characteristics and/or improving capacitance by overcoming spatial limits and/or design rule limits of the MIM capacitor.

### SUMMARY

Aspects of the present disclosure provide an integrated circuit including a capacitor structure having high capacitance in a relatively small size when compared to related capacitors and a non-volatile memory device including the capacitor structure.

According to an aspect of the present disclosure, an integrated circuit is provided. The integrated circuit includes a substrate, and a capacitor structure, disposed above the substrate in a vertical direction, including a first electrode configured to receive a first voltage and including at least one first metal line having a first patterned side surface, a second electrode configured to receive a second voltage and including at least one second metal line having a second patterned side surface, and a dielectric layer disposed between the first electrode and the second electrode. The at least one first metal line and the at least one second metal line extend in a first horizontal direction. The first electrode, the second electrode, and the dielectric layer are disposed on a same layer. The at least one second metal line are spaced apart from the at least one first metal line in a second horizontal direction.

According to an aspect of the present disclosure, an integrated circuit is provided. The integrated circuit includes a substrate, and a capacitor structure, disposed above the substrate in a vertical direction, including a first electrode configured to receive a first voltage, a second electrode configured to receive a second voltage, and a dielectric layer disposed between the first electrode and the second electrode. The first voltage is different from the second voltage. The first electrode includes a first metal line extending in a first horizontal direction and a second metal line extending in the first horizontal direction. The second metal line is disposed above the first metal line in the vertical direction, and is coupled to the first metal line. The second electrode includes a third metal line extending in the first horizontal direction and fourth metal line extending in the first horizontal direction. The third metal line is spaced apart from the first metal line in a second horizontal direction, and is disposed at a same first level as the first metal line. The fourth metal line is spaced apart from the second metal line in the second horizontal direction, is disposed at a same second level as the second metal line, and is coupled to the third metal line. Side surfaces of each of the first metal line, the second metal line, the third metal line, and the fourth metal line include respective patterns extending in the vertical direction.

According to an aspect of the present disclosure, a non-volatile memory device is provided. The non-volatile memory device includes a memory cell array including a plurality of memory cells respectively coupled to a plurality of word lines, and a voltage generator including a charge pump that includes at least one capacitor configured to generate voltages applied to the plurality of word lines. The at least one capacitor includes a first electrode, a dielectric layer, and a second electrode disposed on a same layer. The first electrode includes at least one first metal line having a first patterned side surface, extending in a first horizontal direction, and configured to receive a first voltage. The second electrode includes at least one second metal line having a second patterned side surface, extending in the first horizontal direction, spaced apart from the at least one first metal line in a second horizontal direction, and configured to receive a second voltage. The second voltage is different from the first voltage.

Additional aspects are set forth in part in the description which follows and, in part, may be apparent from the description, or may be learned by practice of the presented embodiments.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1 is a plan view illustrating an integrated circuit, according to an embodiment;

FIG. 2 is a perspective view illustrating the integrated circuit of FIG. 1, according to an embodiment;

FIG. 3A is a cross-sectional view taken along a line X1-X1′ of FIG. 1, according to an embodiment;

FIG. 3B is a cross-sectional view taken along a line X2-X2′ of FIG. 1, according to an embodiment;

FIG. 3C is a cross-sectional view taken along a line X3-X3′ of FIG. 1, according to an embodiment;

FIG. 4A is a cross-sectional view taken along a line Y1-Y1′ of FIG. 1, according to an embodiment;

FIG. 4B is a cross-sectional view taken along a line Y2-Y2′ of FIG. 1, according to an embodiment;

FIG. 5 is a plan view illustrating an integrated circuit, according to an embodiment;

FIG. 6 is a cross-sectional view taken along a line Y3-Y3′ of FIG. 5, according to an embodiment;

FIG. 7 is a cross-sectional view taken along a line Y1-Y1′ of FIG. 5, according to an embodiment;

FIG. 8 is a perspective view illustrating an integrated circuit, according to an embodiment;

FIG. 9 is a plan view illustrating an integrated circuit, according to an embodiment;

FIG. 10 is a plan view illustrating an integrated circuit, according to an embodiment;

FIG. 11 is a perspective view illustrating the integrated circuit of FIG. 10, according to an embodiment;

FIG. 12 is a plan view illustrating an integrated circuit, according to an embodiment;

FIG. 13 is a perspective view illustrating the integrated circuit of FIG. 12, according to an embodiment;

FIG. 14 is a plan view illustrating an integrated circuit, according to an embodiment;

FIG. 15 is a perspective view illustrating the integrated circuit of FIG. 14, according to an embodiment;

FIG. 16 is a plan view illustrating an integrated circuit, according to an embodiment;

FIG. 17A is a perspective view illustrating an integrated circuit, according to an embodiment;

FIG. 17B is a cross-sectional view taken along a line Y4-Y4′ of FIG. 17A, according to an embodiment;

FIG. 18A is a perspective view illustrating an integrated circuit, according to an embodiment;

FIG. 18B is a cross-sectional view taken along a line Y5-Y5′ of FIG. 18A, according to an embodiment;

FIG. 19 is a block diagram illustrating a memory device, according to an embodiment;

FIG. 20 schematically illustrates a structure of a memory device, according to an embodiment;

FIG. 21 is a cross-sectional view of a memory device having a bonding VNAND (B-VNAND) structure, according to an embodiment; and

FIG. 22 is a diagram of a system to which an integrated circuit is applied, according to an embodiment.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures may be omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to described various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment.

As used herein, each of the terms “Al₂O₃”, “CoSi”, “HfO₂”, “NiSi”, “SrTiO₃”, “Ta₂O₅”, “TaN,” “WSi”, “ZrO₂”, and the like may refer to a material made of elements included in each of the terms and is not a chemical formula representing a stoichiometric relationship.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

Hereinafter, embodiments of the present disclosure are described in detail with reference to the accompanying drawings.

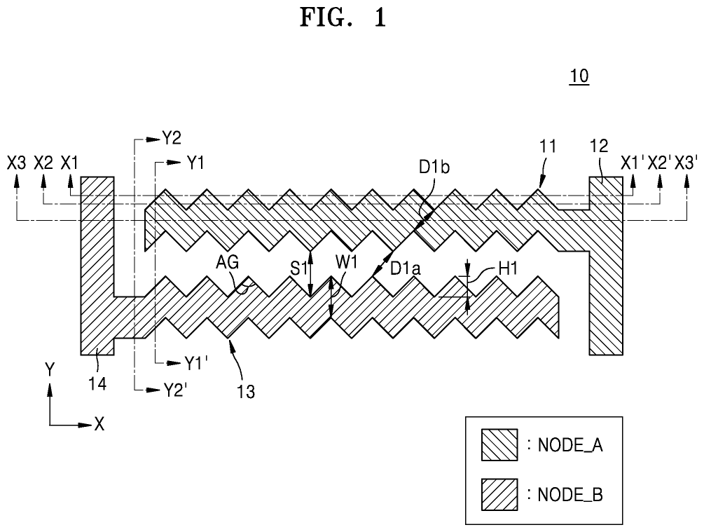

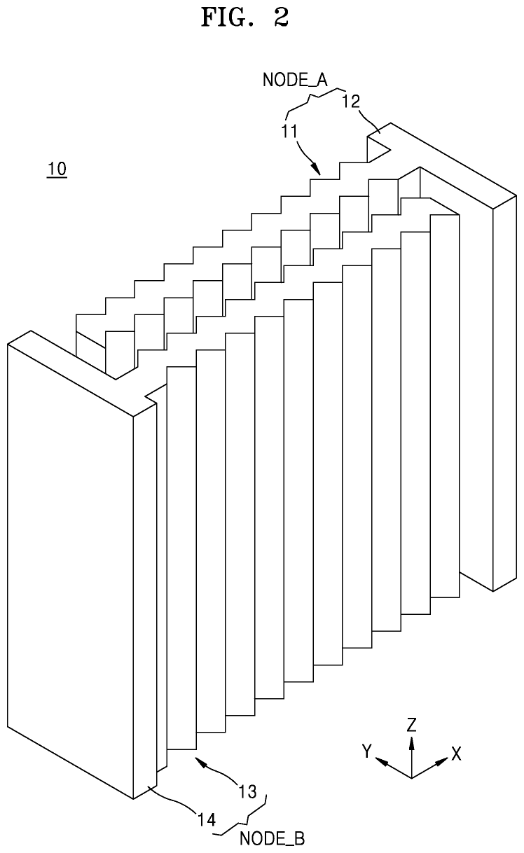

FIG. 1 is a plan view illustrating an integrated circuit 10, according to an embodiment. FIG. 2 is a perspective view illustrating the integrated circuit 10 of FIG. 1, according to an embodiment.

Referring to FIGS. 1 and 2 together, the integrated circuit 10 may include a first metal line 11, a first conductive line 12, a second metal line 13, and a second conductive line 14. In an embodiment, the first metal line 11, the first conductive line 12, the second metal line 13, and the second conductive line 14 may be disposed on a same layer. For example, the first and second metal lines 11 and 13 may have heights in the vertical direction Z that may be substantially similar and/or may be the same height. Alternatively or additionally, the first and second metal lines 11 and 13 may have upper surfaces with levels that may be substantially similar and/or may be the same level. In an optional or additional embodiment, the first and second metal lines 11 and 13 may have lower surfaces with levels that may be substantially similar and/or may be the same level.

In an embodiment, the first metal line 11 may be connected to the first conductive line 12. For example, the first metal line 11 and the first conductive line 12 may constitute a first electrode and/or a first node NODE_A. In an optional or additional embodiment, the second metal line 13 may be connected to the second conductive line 14. For example, the second metal line 13 and the second conductive line 14 may constitute a second electrode and/or a second node NODE_B. A first voltage may be applied to the first electrode and/or the first node NODE_A. Alternatively or additionally, a second voltage may be applied to the second electrode and/or the second node NODE_B. In an embodiment, the voltage level of the first voltage may be different from the voltage level of the second voltage. For example, the first voltage may correspond to the power voltage, and the second voltage may correspond to the ground voltage. Alternatively or additionally, the first voltage may correspond to the ground voltage and the second voltage may correspond to the power voltage. That is, the present disclosure may not be limited in this regard.

An insulating material, a dielectric material, and/or a dielectric layer (not shown) may be disposed between the first electrode (e.g., the first metal line 11 and the first conductive line 12) and the second electrode (e.g., the second metal line 13 and the second conductive line 14). As a result, the first electrode (e.g., NODE_A) and the second electrode (e.g., NODE_B), together with the dielectric layer, may constitute a capacitor structure (e.g., a metal-insulator-metal (MIM) capacitor). Accordingly, the integrated circuit 10 may be referred to as a capacitor structure and/or a MIM capacitor.

However, the capacitor structure according to the present disclosure may not be limited to a MIM capacitor. For example, according to some embodiments, the capacitor structure may be implemented as a metal-insulator-polysilicon (MIP) capacitor, a polysilicon-insulator-metal (PIM) capacitor, and/or a polysilicon-insulator-polysilicon (PIP) capacitor. That is, in such embodiments, the first metal line 11 and/or the second metal line 13 may be implemented with a polysilicon material.

In an embodiment, the MIM capacitor and/or the integrated circuit 10 may be included in a non-volatile memory device. For example, the non-volatile memory device may include a charge pump that may provide a high current to apply voltage to word lines. That is, the charge pump may include the MIM capacitor and/or the integrated circuit 10. In an optional or additional embodiment, the MIM capacitor and/or the integrated circuit 10 may be included in a dynamic random access memory (DRAM) memory device. That is, the present disclosure may not be limited in this regard. For example, the MIM capacitor and/or the integrated circuit 10 may be included in various variable resistance memory devices and/or display devices without deviating from the scope of the present disclosure.

In an embodiment, the first and second metal lines 11 and 13 may each extend in a first horizontal direction (e.g., direction X). In an optional or additional embodiment, the second metal line 13 may be spaced apart from the first metal line 11 in a second horizontal direction (e.g., direction Y). That is, the first metal line 11 and the second metal line 13 may face each other in the second horizontal direction Y. Alternatively or additionally, the first and second conductive lines 12 and 14 may extend in the second horizontal direction Y. The first conductive line 12 may be referred to as a first strap line and the second conductive line 14 may be referred to as a second strap line. In some embodiments, the first and second conductive lines 12 and 14 may have widths in the first horizontal direction X that may be substantially similar and/or may be the same width. However, the present disclosure may not be limited in this regard.

In an embodiment, a surface (e.g., a side surface) of each of the first and second metal lines 11 and 13 may have a certain pattern. That is, at least one surface of each of the first and second metal lines 11 and 13 may have a regular (e.g., repeated) pattern in the first horizontal direction X. Alternatively or additionally, the pattern may extend in the vertical direction Z. For example, the first metal line 11 may have a first patterned surface having a first pattern, and the second metal line 13 may have a second patterned surface having a second pattern. In an embodiment, the first pattern and the second pattern may have an engagement (e.g., interlocking) structure. Alternatively or additionally, the first pattern and the second pattern may be substantially similar and/or may be the same pattern. In such an example, the first and second metal lines 11 and 13 may be formed using the same mask.

In an embodiment, the side surface of each of the first and second metal lines 11 and 13 may have a saw pattern. Consequently, the surface area of the first and second metal lines 11 and 13 may be significantly increased compared to a surface area of comparable metal lines that may have a substantially flat side surface. Accordingly, a capacitance of the capacitor structure (e.g., the MIM capacitor) configured by the first and second metal lines 11 and 13 having the saw pattern may be greater than another capacitance of another capacitor structure using the metal lines having the substantially flat surface.

According to an embodiment, the first metal line 11 may have a first patterned side surface having a saw pattern, and the second metal line 13 may have a second patterned side surface having a saw pattern. However, the present disclosure may not be limited in this regard. That is, the first metal line 11 may have a first flat side surface and/or the second metal line 13 may have a second flat side surface. Consequently, the surface area of each of the first and second patterned side surfaces may be greater than the surface area of each of the first and second flat side surfaces. For example, the surface area of each of the first and second patterned side surfaces may correspond to approximately 1.4 times the surface area of each of the first and second flat side surfaces.

In an embodiment, the first and second metal lines 11 and 13 may be spaced apart by a first space S1 in the second horizontal direction Y. In an optional or additional embodiment, each of the first and second metal lines 11 and 13 may have a first width W1 in the second horizontal direction Y. Alternatively or additionally, the first and second metal lines 11 and 13 may have different widths in the second horizontal direction Y. That is, the first space S1 and/or the first width W1 may be changed in various ways according to embodiments and/or design constraints implemented on integrated circuit 10.

In an embodiment, the side surface of each of the first and second metal lines 11 and 13 may have a saw pattern in which each saw shape in the saw pattern may have a first height H1 and a first angle AG. For example, the first height H1 may be approximately 20 nanometers (nm). For another example, the first angle AG may be approximately 90 degrees (e.g., 90°). However, the present disclosure may not be limited in this regard. That is, it is to be understood that the first height H1 and/or the first angle AG may be changed in various ways according to embodiments and/or design constraints implemented on the integrated circuit 10. In an optional or additional embodiment, the first space S1 may be decreased as the first height H1 may decrease and, thus, the capacitance of the MIM capacitor structure may increase.

In an embodiment, the first and second side surfaces of the first metal line 11 facing each other may have a saw pattern. Alternatively or additionally, the first and second side surfaces of the second metal line 13 facing each other may have a saw pattern. In an optional or additional embodiment, the second side surface of the first metal line 11 and the first side surface of the second metal line 13 may face each other. For example, a protruding portion of the saw pattern on the second side surface of the first metal line 11 may be spaced apart from a protruding portion of the saw pattern on the first side surface of the second metal line 13 by a first distance D1a. Alternatively or additionally, a concave portion of the first side surface of the first metal line 11 may be spaced apart from a concave portion of the second side surface of the first metal line 11 by a second distance D1b. Similarly, a concave portion of the first side surface of the second metal line 13 may be spaced apart from a concave portion of the second side surface by a second distance D1b. It is to be understood that the first and/or second distances D1a and D1b may be changed in various ways according to embodiments and/or design constraints implemented on the integrated circuit 10.

Although FIG. 1 illustrates the side surfaces of the first and second metal lines 11 and 13 as having a saw pattern, it is to be understood that the side surfaces of the first and second metal lines 11 and 13 may have other repeating patterns without deviating from the scope of the present disclosure. For example, the side surfaces of the first and second metal lines 11 and 13 may have another repeating pattern that increases the surface area of the side surfaces of the first and second metal lines 11 and 13 when compared with side surfaces that have a substantially flat surface.

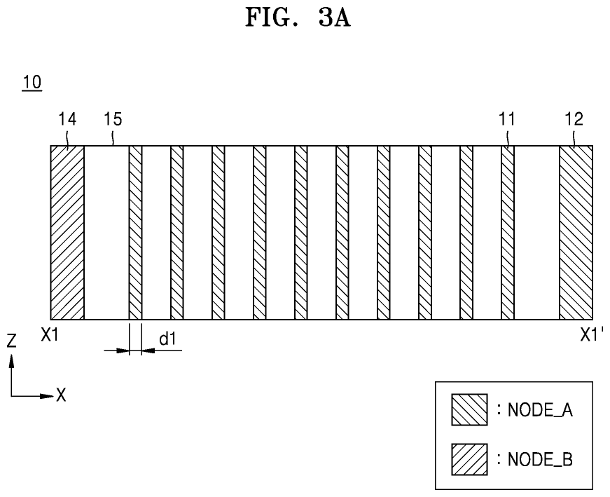

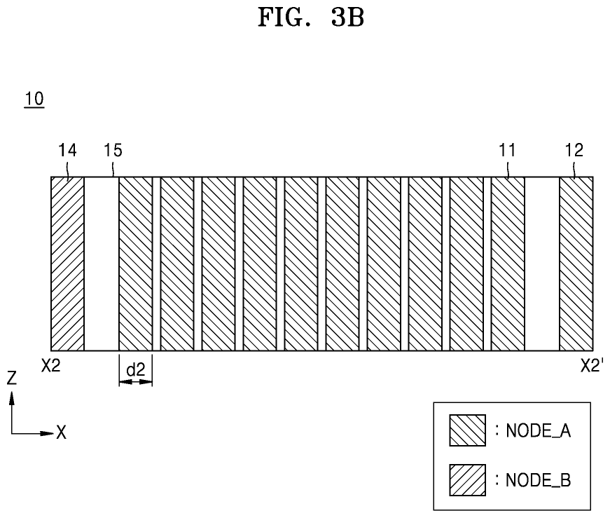

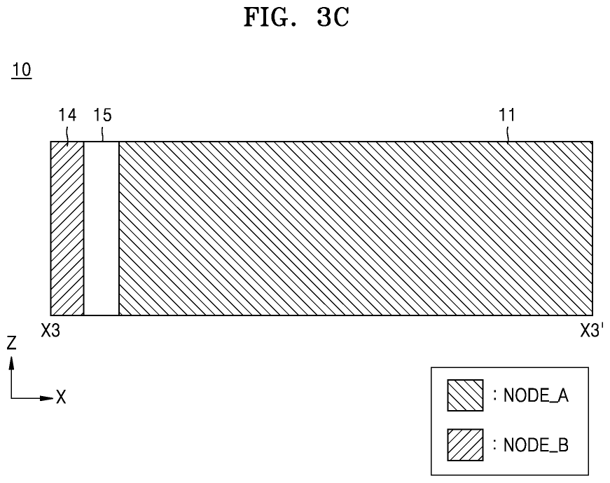

FIG. 3A is a cross-sectional view taken along a line X1-X1′ of FIG. 1, according to an embodiment. FIG. 3B is a cross-sectional view taken along a line X2-X2′ of FIG. 1, according to an embodiment. FIG. 3C is a cross-sectional view taken along a line X3-X3′ of FIG. 1, according to an embodiment.

Referring to FIGS. 1, 3A, 3B, and 3C together, a dielectric layer 15 may be disposed between the first metal line 11, the first conductive line 12, and the second conductive line 14. Alternatively or additionally, the first metal line 11, the first conductive line 12, the second conductive line 14, and the dielectric layer 15 may be disposed on a same layer.

In an embodiment, the dielectric layer 15 may include a material having a high dielectric constant (e.g., a high-k dielectric material). For example, the dielectric layer 15 may include hafnium dioxide (HfO₂), which may be a high dielectric material. For another example, the dielectric layer 15 may include any one of dielectric films having a dielectric constant equal to or greater than nine (9), such as, but not limited to, aluminum oxide (Al₂O₃), zirconium dioxide (ZrO₂), tantalum pentoxide (Ta₂O₅), strontium titanate (SrTiO₃), and the like, or a mixture film thereof. However, the present disclosure may not be limited in this regard. For example, the dielectric layer 15 may include silicon oxide (SiO). Alternatively or additionally, the dielectric layer 15 may include, but not be limited to, plasma enhanced oxide (PEOX), tetraethyl orthosilicate (TEOS), boro tetraethyl orthosilicate (BTEOS), phosphorous tetraethyl orthosilicate (PTEOS), boro phospho tetraethyl orthosilicate (BPTEOS), boro silicate glass (BSG), phospho silicate glass (PSG), boro phospho silicate glass (BPSG), and the like.

In an embodiment, the first metal line 11 may have a saw pattern repeated in the first horizontal direction X and extending in the vertical direction Z. Accordingly, in FIG. 3A, the first metal line 11 may have a first width d1 in the first horizontal direction X, in FIG. 3B, the first metal line 11 may have a second width d2 greater than the first width d1 in the first horizontal direction X, and in FIG. 3C, the first metal line 11 may continuously extend in the first horizontal direction X.

According to an embodiment, when the first metal line 11 has a pattern extending in the vertical direction Z, the width of the first metal line 11 in the cross section in the first horizontal direction X may be constant in the vertical direction Z. Similarly, when the second metal line 13 also has a pattern extending in the vertical direction Z, the width of the second metal line 13 in the cross section in the first horizontal direction X may be constant in the vertical direction Z.

The first height H1 of the saw pattern on the surface of the first metal line 11 may be changed according to embodiments, and the width of the first metal line 11 may be changed according to the position of the cross section in the first horizontal direction Z. For example, in the saw shape of the first metal line 11, as the distance from the center of the first metal line 11 in the second horizontal direction Y increases, the width of the first metal line 11 in the first horizontal direction X may decrease. Alternatively or additionally, in the saw shape of the second metal line 13, as the distance from the center of the second metal line 13 in the second horizontal direction Y decreases, the width of the second metal line 13 in the first horizontal direction X may increase.

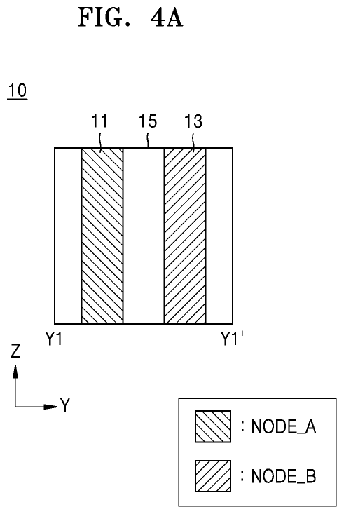

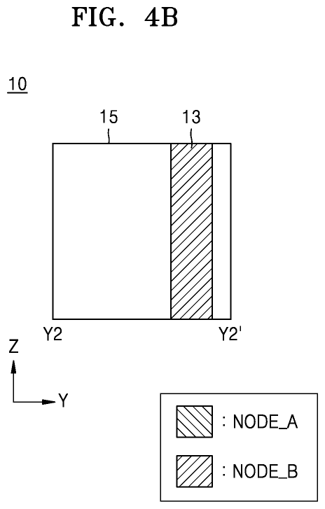

FIG. 4A is a cross-sectional view taken along a line Y1-Y1′ of FIG. 1, according to an embodiment. FIG. 4B is a cross-sectional view taken along a line Y2-Y2′ of FIG. 1, according to an embodiment.

Referring to FIGS. 1, 4A, and 4B together, the dielectric layer 15 may be disposed between the first metal line 11 and the second metal line 13, and the first and second metal lines 11 and 13 and the dielectric layer 15 may be disposed on a same layer.

In an embodiment, the first and second metal lines 11 and 13 may have a saw pattern extending in the vertical direction Z. Accordingly, in FIG. 4A, each of the first and second metal lines 11 and 13 may have the first width W1 in the second horizontal direction Y. In an optional or additional embodiment, the first metal line 11 may be connected to the first conductive line 12 and may not be connected to the second conductive line 14. Alternatively or additionally, the second metal line 13 may not be connected to the first conductive line 12 and may be connected to the second conductive line 14. Accordingly, in FIG. 4B, the first metal line 11 may not be disposed.

According to an embodiment, when the first metal line 11 has a pattern extending in the vertical direction Z, the width of the first metal line 11 in the cross section in the second horizontal direction Y may be constant in the vertical direction Z. Similarly, when the second metal line 13 also has a pattern extending in the vertical direction Z, the width of the second metal line 13 in the cross section in the second horizontal direction Y may be constant in the vertical direction Z.

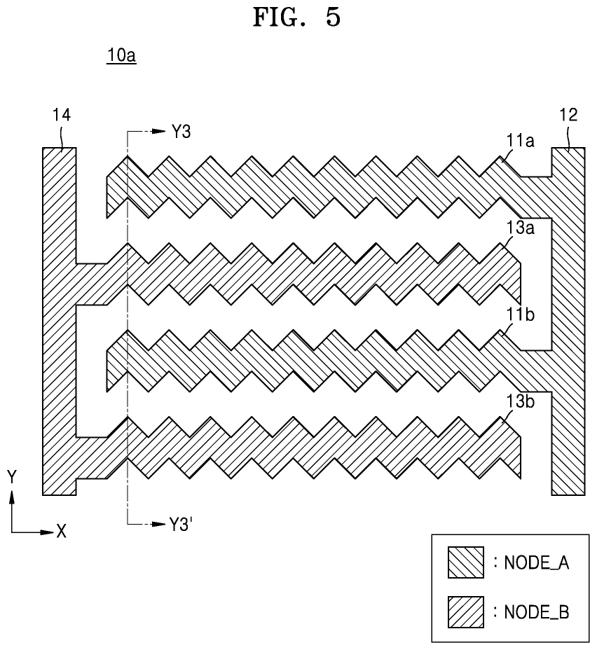

FIG. 5 is a plan view illustrating an integrated circuit 10a, according to an embodiment.

Referring to FIG. 5, the integrated circuit 10a may include a plurality of first metal lines 11a and 11b, a plurality of second metal lines 13a and 13b, the first conductive line 12, and the second conductive line 14. The integrated circuit 10a may include or may be similar in many respects to the integrated circuit 10 described above with reference to FIGS. 1 to 4B, and may include additional features not mentioned above. Thus, the above-described features of the integrated circuit 10 may also be applied to the integrated circuit 10a.

In an embodiment, the plurality of first metal lines 11a and 11b, the plurality of second metal lines 13a and 13b, the first conductive line 12, and the second conductive line 14 may be disposed on a same layer. For example, the plurality of first metal lines 11a and 11b, the plurality of second metal lines 13a and 13b, the first conductive line 12, and the second conductive line 14 may have heights in the vertical direction Z that may be substantially similar and/or may be the same height. Alternatively or additionally, the plurality of first metal lines 11a and 11b, the plurality of second metal lines 13a and 13b, the first conductive line 12, and the second conductive line 14 may have upper surfaces with levels that may be substantially similar and/or may be the same level. In an optional or additional embodiment, the plurality of first metal lines 11a and 11b, the plurality of second metal lines 13a and 13b, the first conductive line 12, and the second conductive line 14 may have lower surfaces with levels that may be substantially similar and/or may be the same level.

In an embodiment, the plurality of first metal lines 11a and 11b may be connected to the first conductive line 12. For example, the plurality of first metal lines 11a and 11b and the first conductive line 12 may constitute a first electrode and/or the first node NODE_A. In an optional or additional embodiment, the plurality of second metal lines 13a and 13b may be connected to the second conductive line 14. For example, the plurality of second metal lines 13a and 13b and the second conductive line 14 may constitute a second electrode and/or the second node NODE_B. A first voltage may be applied to the first node NODE_A. Alternatively or additionally, a second voltage may be applied to the second node NODE_B. In an embodiment, the voltage level of the first voltage may be different from the voltage level of the second voltage. For example, the first voltage may correspond to the power voltage, and the second voltage may correspond to the ground voltage. Alternatively or additionally, the first voltage may correspond to the ground voltage and the second voltage may correspond to the power voltage. That is, the present disclosure may not be limited in this regard.

An insulating material, a dielectric material and/or a dielectric layer (not shown) may be disposed between the first electrode (constituted by the plurality of first metal lines 11a and 11b) and the second electrode (constituted by the plurality of second metal lines 13a and 13b and the second conductive line 14). As a result, the first electrode (e.g., NODE_A) and the second electrode (e.g., NODE_B), together with the dielectric layer, may constitute a capacitor structure (e.g., a MIM capacitor).

In an embodiment, the plurality of first metal lines 11a and 11b and the plurality of second metal lines 13a and 13b may extend, respectively, in the first horizontal direction X. In an optional or additional embodiment, the second metal line 13a may be spaced apart from the first metal line 11a in the second horizontal direction Y. That is, the first metal line 11b may be spaced apart from the second metal line 13a in the second horizontal direction Y, and/or the second metal line 13b may be spaced apart from the first metal line 11b in the second horizontal direction Y. Alternatively or additionally, the plurality of first metal lines 11a and 11b and the plurality of second metal lines 13a and 13b may be alternately arranged. For example, the first metal line 11a, the second metal line 13a, the first metal line 11b, and the second metal line 13b may be sequentially arranged in the second horizontal direction Y.

In an embodiment, the first and second conductive lines 12 and 14 may extend in the second horizontal direction Y. The number of the plurality of first metal lines 11a and 11b connected to the first conductive line 12 may vary according to embodiments and/or design constraints implemented on the integrated circuit 10a. Alternatively or additionally, the number of the plurality of second metal lines 13a and 13b connected to the second conductive line 14 may vary according to embodiments and/or design constraints implemented on the integrated circuit 10a. For example, the first and second conductive lines 12 and 14 may have widths in the first horizontal direction X that may be substantially similar and/or may be the same width. However, the present disclosure may not be limited in this regard.

In an embodiment, a surface (e.g., a side surface) of each of the plurality of first metal lines 11a and 11b and the plurality of second metal lines 13a and 13b may have a certain pattern. That is, at least one surface of each of the plurality of first metal lines 11a and 11b and the plurality of second metal lines 13a and 13b may have a regular (e.g., repeating) pattern in the first horizontal direction X. Alternatively or additionally, the pattern may extend in the vertical direction Z. For example, at least one surface of each of the plurality of first metal lines 11a and 11b and the plurality of second metal lines 13a and 13b may have a saw pattern. However, the present disclosure may not be limited in this regard.

In an embodiment, at least one surface (e.g., a side surface) of each of the plurality of first metal lines 11a and 11b may have a first pattern, and/or at least one surface (e.g., a side surface) of each of the plurality of second metal lines 13a and 13b may have a second pattern. In an embodiment, the first pattern and the second pattern may have an engagement (e.g., interlocking) structure. Alternatively or additionally, the first pattern may be substantially and/or the same as the second pattern. Consequently, the plurality of first metal lines 11a and 11b and the plurality of second metal lines 13a and 13b may be formed by using a same mask.

In an embodiment, at least one surface (e.g., a side surface) of each of the plurality of first metal lines 11a and 11b and the plurality of second metal lines 13a and 13b may have a certain pattern (e.g., a saw pattern). Consequently, the surface area of the plurality of first metal lines 11a and 11b and the plurality of second metal lines 13a and 13b may be significantly increased compared to a surface area of comparable metal lines that may have a substantially flat surface. Accordingly, the capacitance of the capacitor structure (e.g., the MIM capacitor) configured by the plurality of first metal lines 11a and 11b and the plurality of second metal lines 13a and 13b having a patterned surface may be greater than the capacitance of another capacitor structure using metal lines having substantially flat surfaces.

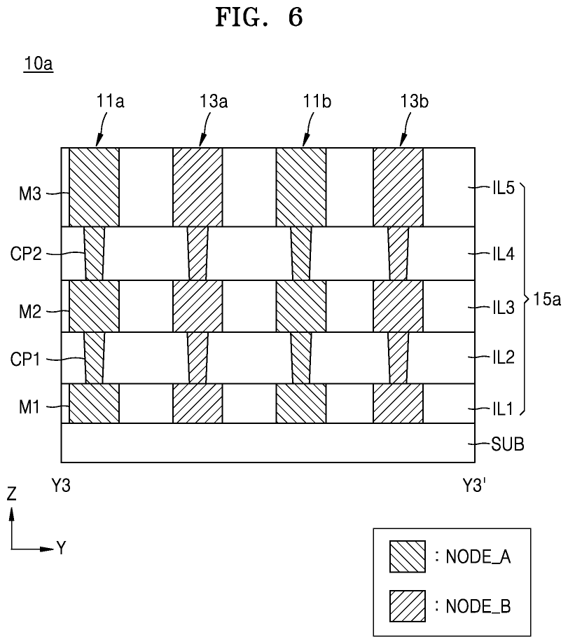

FIG. 6 is a cross-sectional view taken along a line Y3-Y3′ of FIG. 5, according to an embodiment.

Referring to FIG. 6, the integrated circuit 10a may include a first metal layer M1, a second metal layer M2, and a second metal layer M3 disposed on a substrate SUB. The substrate SUB may be a semiconductor substrate including a semiconductor material. For example, the substrate SUB may include a semiconductor material such as, but not limited to, silicon (Si), germanium (Ge), silicon-germanium (Si—Ge), and the like, and may further include, but not be limited to, an epitaxial layer, a silicon on insulator (SOI) layer, a germanium on insulator (GOI) layer, a semiconductor on insulator (SeOI) layer, and the like. For example, the substrate SUB may include a P-type substrate. A main surface of the substrate SUB may extend in the first horizontal direction X and the second horizontal direction Y. Hereinafter, a direction substantially perpendicular to the upper surface of the substrate SUB may be referred to as the vertical direction Z, and two directions substantially parallel to the upper surface of the substrate SUB may be referred to as the first horizontal direction X and the second horizontal direction Y. The first horizontal direction X and the second horizontal direction Y may be substantially perpendicular to each other.

The first metal layer M1 and the second metal layer M2 may be connected through a first contact CP1, and the second metal layer M2 and the third metal layer M3 may be connected through a second contact CP2. The integrated circuit 10a may further include an insulating layer and/or the dielectric layer 15a disposed on the substrate SUB. The dielectric layer 15a may include a first insulating layer and/or a first dielectric layer IL1 disposed on the same level as the first metal layer M1, a second insulating layer and/or a second dielectric layer IL2 disposed on the same level as the first contact CP1, a third insulating layer and/or a third dielectric layer IL3 disposed on the same level as the second metal layer M2, a fourth insulating layer and/or a fourth dielectric layer IL4 disposed on the same level as the second contact CP2, and a fifth insulating layer and/or a fifth dielectric layer IL5 disposed on the same level as the third metal layer M3.

Each of the first to fifth insulating layers IL1 to IL5 may include a material having a large dielectric constant (e.g., a high-k dielectric material). For example, each of the first to fifth insulating layers IL1 to IL5 may include hafnium dioxide (HfO₂), which may be a high dielectric material. For another example, each of the first to fifth insulating layers IL1 to IL5 may include any one of dielectric films having a dielectric constant equal to or greater than nine (9), such as, but not limited to, aluminum oxide (Al₂O₃), zirconium dioxide (ZrO₂), tantalum pentoxide (Ta₂O₅), strontium titanate (SrTiO₃), and the like, or a mixture film thereof. However, the present disclosure may not be limited in this regard. For example, each of the first to fifth insulating layers IL1 to IL5 may include silicon oxide (SiO). Alternatively or additionally, each of the first to fifth insulating layers IL1 to IL5 may include, but not be limited to, plasma enhanced oxide (PEOX), tetraethyl orthosilicate (TEOS), boro tetraethyl orthosilicate (BTEOS), phosphorous tetraethyl orthosilicate (PTEOS), boro phospho tetraethyl orthosilicate (BPTEOS), boro silicate glass (BSG), phospho silicate glass (PSG), boro phospho silicate glass (BPSG), and the like.

In an embodiment, each of the first metal lines 11a and 11b and the second metal lines 13a and 13b may include the first metal layer M1, the first contact CP1, the second metal layer M2, the second contact CP2, and the third metal layer M3 disposed in the vertical direction Z. The voltage of the first node NODE_A may be applied to the first metal lines 11a and 11b. Alternatively or additionally, the voltage of the second node NODE_B may be applied to the second metal lines 13a and 13b. In an optional or additional embodiment, the first and second metal lines 11a, 11b, 13a, and 13b, together with the dielectric layer 15a, may constitute a capacitor structure (e.g., a MIM capacitor). For example, the first and second metal lines 11a, 11b, 13a, and 13b and the dielectric layer 15a may constitute a vertical capacitor structure (e.g., a vertical MIM capacitor).

In an embodiment, each of the first to third metal layers M1, M2, and M3 and/or the first and second contacts CP1 and CP2 may include a metal material such as, but not limited to, tungsten (W), tungsten nitride (WN), titanium (Ti), titanium nitride (TiN), tantalum (Ta), tantalum nitride (TaN), platinum (Pt), cobalt (Co) and aluminum (Al) and/or a silicide material including polysilicon, tungsten silicide (WSi), cobalt silicide (CoSi) and nickel silicide (NiSi), and/or a combination thereof.

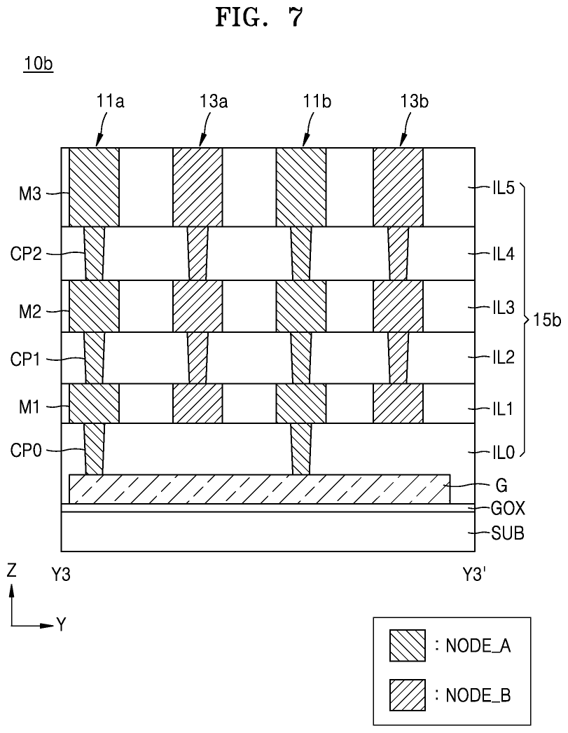

FIG. 7 is a cross-sectional view taken along a line Y3-Y3′ of FIG. 5, according to an embodiment.

Referring to FIG. 7, an integrated circuit 10b may include a gate insulating layer GOX, a gate G, and an insulating layer IL0 disposed on the substrate SUB. For example, the gate insulating layer GOX may include a metal oxide having a high dielectric constant (e.g., zirconium oxide (ZrO₂), aluminum oxide (Al₂O₃), tantalum oxide (Ta₂O₃), and/or hafnium oxide (HfO₂)). However, the present disclosure may not be limited in this regard. For example, the gate insulating layer GOX may include, but not be limited to, an oxide-based material such as silicon oxide (SiO), silicon carbonate (SiCO), and/or silicon oxyfluoride (SiOF). In an embodiment, a gate electrode and/or the gate G may be disposed on the gate insulating layer GOX. The gate G may include a metal material such as, but not limited to, tungsten (W) and tantalum (Ta), nitrides thereof, silicides thereof, doped polysilicon, and the like. Alternatively or additionally, the gate G may be formed using a deposition process.

The integrated circuit 10b may include or may be similar in many respects to the integrated circuit 10a of FIGS. 5 and 6, and may include additional features not mentioned above. Thus, the above-described features of the integrated circuit 10a may also be applied to the integrated circuit 10b.

In an embodiment, each of the first metal lines 11a and 11b may be connected to the gate G through the contact CP0. The dielectric layer 15b may include the insulating layer IL0 covering an upper surface of the gate G, a first insulating layer and/or first dielectric layer IL1, a second insulating layer and/or the second dielectric layer IL2, a third insulating layer and/or the third dielectric layer IL3, a fourth insulating layer and/or the fourth dielectric layer IL4, and a fifth insulating layer and/or the fifth dielectric layer IL5.

Referring to FIG. 7, in an embodiment, each of the first metal lines 11a and 11b may include the contact CP0, the first metal layer M1, the first contact CP1, the second metal layer M2, the second contact CP2, and the third metal layer M3 disposed in the vertical direction Z, and each of the second metal lines (e.g., second metal lines 13a, 13b) may include the first metal layer M1, the first contact CP1, the second metal layer M2, the second contact CP2, and the third metal layer M3 disposed in the vertical direction Z. The voltage of the first node NODE_A, for example, a gate voltage, may be applied to the first metal lines 11a and 11b and the gate G. Alternatively or additionally, the voltage of the second node NODE_B may be applied to the second metal lines 13a and 13b. In an optional or additional embodiment, the first and second metal lines 11a, 11 b, 13a, and 13b may constitute a capacitor structure (e.g., a MIM capacitor) together with the dielectric layer 15b. For example, the first and second metal lines 11a, 11 b, 13a, and 13b and the dielectric layer 15b may constitute a vertical capacitor structure (e.g., a vertical MIM capacitor).

Although not shown, source/drain regions may be disposed on both sides of the gate G in the first horizontal direction X. In an embodiment, the first metal lines 11a and 11b may be connected to the gate G, and the second metal lines 13a and 13b may be connected to a source region and/or a drain region. For example, the source/drain regions may be formed by doping N+ impurities in exposed portions of the substrate SUB. In an embodiment, a same voltage (e.g., a second voltage) may be applied to the source region and the drain region. Accordingly, a lower structure of the vertical capacitor structure may not operate as a metal-oxide-semiconductor (MOS) transistor, and a turn-on current may not flow in a channel region between the source region and the drain region. In this case, the gate G may form a channel capacitor with a channel region between the source/drain regions. In an embodiment, the integrated circuit 10b may further include the channel capacitor as well as the vertical capacitor and, as a result, a capacitor integration of a vertical capacitor structure may be improved and a capacitance per unit area may be further increased.

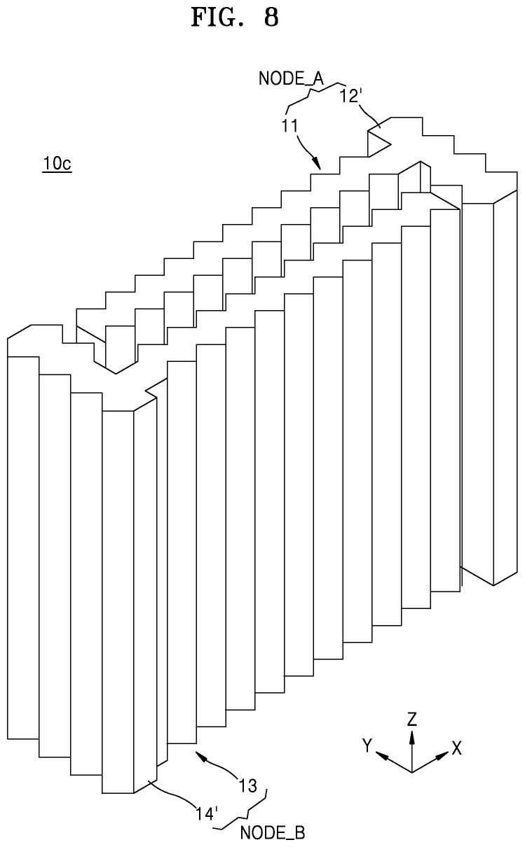

FIG. 8 is a perspective view illustrating an integrated circuit 10c, according to an embodiment. The integrated circuit 10c may include or may be similar in many respects to the integrated circuit 10 of FIG. 2, and may include additional features not mentioned above. Thus, the above-described features of the integrated circuit 10 may also be applied to the integrated circuit 10c.

Referring to FIG. 8, the integrated circuit 10c may include the first and second metal lines 11 and 13, a first conductive line 12′, and a second conductive line 14′. In an embodiment, a surface (e.g., a side surface) of each of the first and second conductive lines 12′ and 14′ may have a certain pattern. That is, at least one surface of each of the first and second conductive lines 12′ and 14′ may have a regular (e.g., repeating) pattern in the first horizontal direction X. Alternatively or additionally, the pattern may extend in the vertical direction Z. For example, at least one surface of each of the first and second conductive lines 12′ and 14′ may have a saw pattern. Thus, the surface area of each of the first and second conductive lines 12′ and 14′ may be significantly increased compared to a surface area of comparable conductive lines that may have substantially flat surfaces. Accordingly, the capacitance of the capacitor structure (e.g., the MIM capacitor) configured by the first and second metal lines 11 and 13 and the first and second conductive lines 12′ and 14′ may be greater than the capacitance of another capacitor structure using metal lines having substantially flat surfaces.

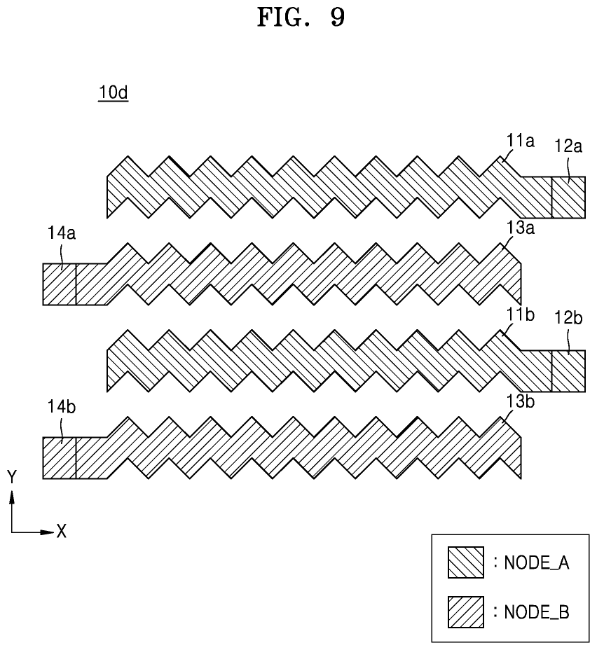

FIG. 9 is a plan view illustrating an integrated circuit 10d, according to an embodiment. The integrated circuit 10d may include or may be similar in many respects to the integrated circuit 10a of FIG. 5, and may include additional features not mentioned above. Thus, the above-described features of the integrated circuit 10a may also be applied to the integrated circuit 10d.

Referring to FIG. 9, the integrated circuit 10d may include a plurality of first metal lines 11a and 11b, a plurality of second metal lines 13a and 13b, a plurality of first conductive lines 12a and 12b, and a plurality of second conductive lines 14a and 14b. The integrated circuit 10d may include the plurality of first conductive lines 12a and 12b instead of the first conductive line 12 extending in the second horizontal direction Y and the plurality of second conductive lines 14a and 14b instead of the second conductive line 14 extending in the second horizontal direction Y, when compared to the integrated circuit 10a of FIG. 5. In an embodiment, the plurality of first metal lines 11a and 11b and the plurality of second metal lines 13a and 13b may be formed using a same mask. In an optional or additional embodiment, the size of the integrated circuit 10d in the first horizontal direction X may be smaller than the size of the integrated circuit 10a of FIG. 5 in the first horizontal direction X.

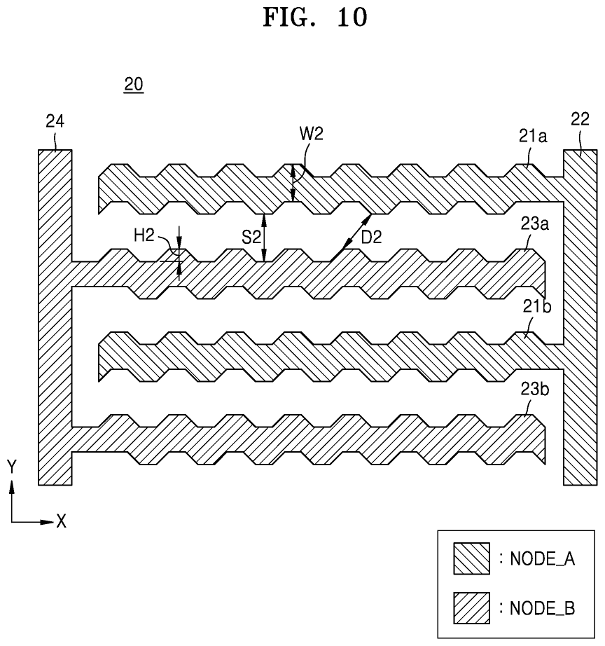

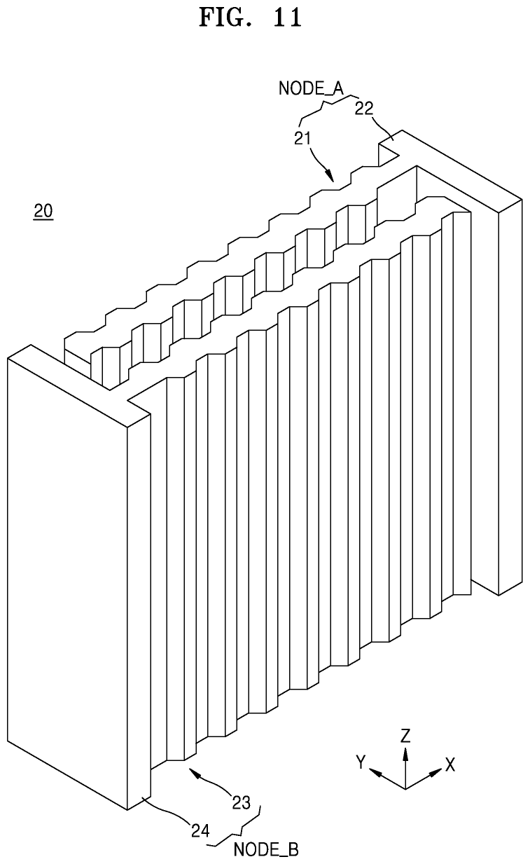

FIG. 10 is a plan view illustrating an integrated circuit 20, according to an embodiment. FIG. 11 is a perspective view illustrating the integrated circuit 20 of FIG. 10, according to an embodiment.

Referring to FIGS. 10 and 11 together, the integrated circuit 20 may include first metal lines 21a and 21b, second metal lines 23a and 23b, a first conductive line 22, and a second conductive line 24. The first metal lines 21a and 21b, the first conductive line 22, the second metal lines 23a and 23b, and the second conductive line 24 may be disposed on a same layer. For example, the first metal lines 21a and 21b, the first conductive line 22, the second metal lines 23a and 23b, and the second conductive line 24 may have heights in the vertical direction Z that may be substantially similar and/or may be the same height. Alternatively or additionally, the first metal lines 21a and 21b, the first conductive line 22, the second metal lines 23a and 23b, and the second conductive line 24 may have upper surfaces with levels that may be substantially similar and/or may be the same level. In an optional or additional embodiments, the first metal lines 21a and 21b, the first conductive line 22, the second metal lines 23a and 23b, and the second conductive line 24 may have lower surfaces with levels that may be substantially similar and/or may be the same level.

The first metal lines 21a and 21b may be connected to the first conductive line 22 to form the first node NODE_A. The second metal lines 23a and 23b may be connected to the second conductive line 24 to form the second node NODE_B. A first voltage may be applied to the first node NODE_A. Alternatively or additionally, a second voltage may be applied to the second node NODE_B. In an embodiment, the voltage level of the first voltage may be different from the voltage level of the second voltage. For example, the first voltage may correspond to the power voltage, and the second voltage may correspond to the ground voltage. Alternatively or additionally, the first voltage may correspond to the ground voltage and the second voltage may correspond to the power voltage. That is, the present disclosure may not be limited in this regard.

An insulating material, a dielectric material, and/or a dielectric layer (not shown) may be disposed between the first metal lines 21a and 21b and the first conductive line 22 and between the second metal lines 23a and 23b and the second conductive line 24. Accordingly, the first and second metal lines 21a, 21b, 23a, and 23b and the first and second conductive lines 22 and 24, together with the dielectric layer, may constitute a capacitor structure (e.g., a MIM capacitor).

Each of the first and second metal lines 21a, 21b, 23a, and 23b may extend in the first horizontal direction X. Each of the first and second conductive lines 22 and 24 may extend in the second horizontal direction Y. For example, the first and second conductive lines 22 and 24 may have widths in the first horizontal direction X that may be substantially similar and/or may be the same width. However, the present disclosure may not be limited in this regard.

In an embodiment, at least one surface (e.g., a side surface) of each of the first and second metal lines 21a, 21b, 23a, and 23b may have a polygonal pattern. For example, the polygonal pattern may include, but not be limited to, a trapezoidal pattern. In an embodiment, the surface of each of the first metal lines 21a and 21b may have a first pattern, and the surface of each of the second metal lines 23a and 23b may have a second pattern. Alternatively or additionally, the first pattern and the second pattern may have an engagement (e.g., interlocking) structure. In an optional or additional embodiment, the first pattern and the second pattern may be the same. Accordingly, the first and second metal lines 21a, 21b, 23a, and 23b may be formed using the same mask.

In an embodiment, when the side surface and/or the surface of each of the first and second metal lines 21a, 21b, 23a, and 23b has the trapezoidal pattern, a surface area of the side surface and/or a surface of each of the first and second metal lines 21a, 21b, 23a, and 23b may be significantly increased compared to a surface area of comparable metal lines may have a substantially flat surface. Thus, the capacitance of the capacitor structure (e.g., an MIM capacitor structure) configured by the first and second metal lines 21a, 21b, 23a, and 23b may be greater than the capacitance of another capacitor structure using the metal lines having the substantially flat surfaces.

According to an embodiment, each of the first metal lines 21a and 21b may have a first patterned side surface having the trapezoidal pattern. Alternatively or additionally, each of the second metal lines 23a and 23b may have a second patterned side surface having the trapezoidal pattern. However, the present disclosure may not be limited in this regard. That is, each of the first metal lines 21a and 21b may have a first flat side surface, and each of the second metal lines 23a and 23b may have a second flat side surface. Consequently, the surface area of each of the first and second patterned side surfaces may be greater than the surface area of each of the first and second flat side surfaces. For example, the surface area of each of the first and second patterned side surfaces may correspond to approximately 1.2 times the surface area of each of the first and second flat side surfaces.

In an embodiment, the first and second metal lines 21a and 23a may be spaced apart by the second space S2 in the second horizontal direction Y. In an optional or additional embodiment, each of the first and second metal lines 21a and 23a may have a second width W2 in the second horizontal direction Y. Alternatively or additionally, the first and second metal lines 21a, 21b, 23a, and 23b may have different widths in the second horizontal direction Y. That is, the second space S2 and/or the second width W2 may be changed in various ways according to embodiments and/or design constraints implemented on the integrated circuit 20.

In an embodiment, the surface of each of the first and second metal lines 21a, 21b, 23a, and 23b may have a trapezoidal pattern in which each trapezoidal shape in the trapezoidal pattern may have a second height H2. The second height H2 may be changed in various ways according to embodiments and/or design constraints implemented on the integrated circuit 20. Alternatively or additionally, the length of the upper side of each trapezoid of the trapezoidal pattern may be changed in various ways according to embodiments and/or design constraints implemented on the integrated circuit 20. In an optional or additional embodiment, an angle formed by an upper side and a lateral side of each trapezoid of the trapezoidal pattern may also be changed in various ways according to embodiments and/or design constraints implemented on the integrated circuit 20.

In an embodiment, the first and second surfaces of the first metal line 21a facing each other may have a trapezoidal pattern. Alternatively or additionally, the first and second surfaces of the second metal line 23a facing each other may have a trapezoidal pattern. In an optional or additional embodiment, the second surface of the first metal line 21a and the first surface of the second metal line 23a may face each other. For example, a trapezoidal protrusion on the second surface of the first metal line 21a may be spaced apart from a trapezoidal protrusion on the first surface of the second metal line 23a by a second distance D2. The second distance D2 may be changed in various ways according to embodiments and/or design constraints implemented on the integrated circuit 20.

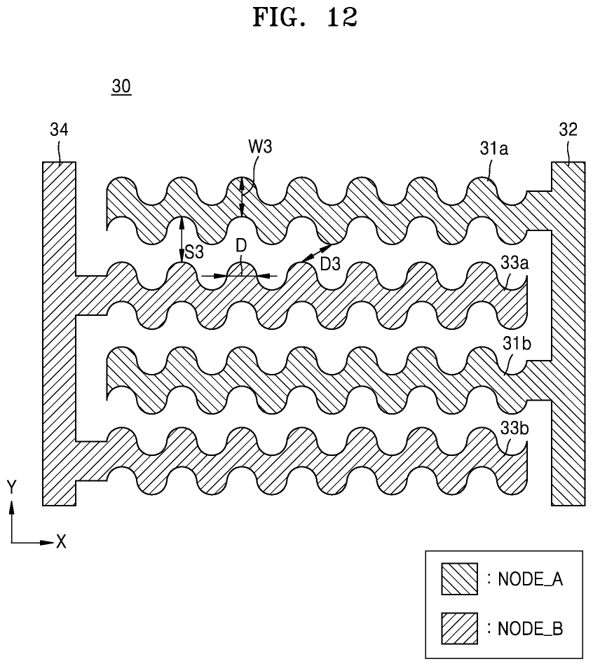

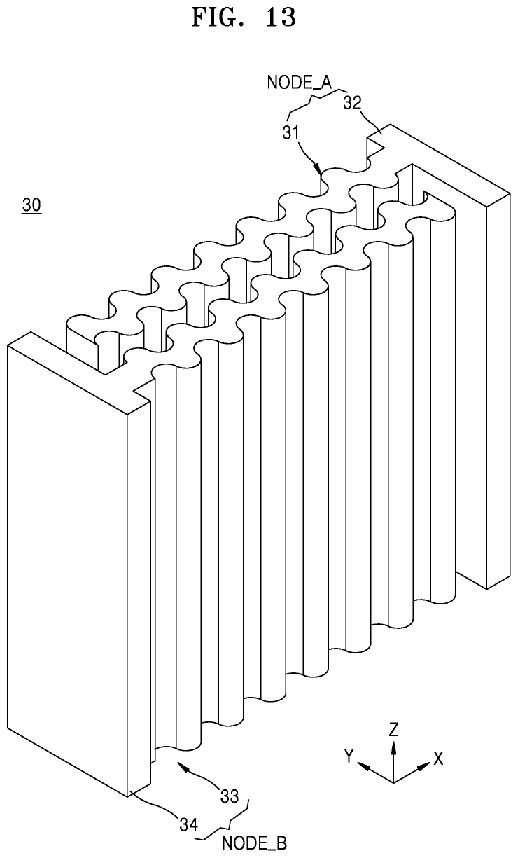

FIG. 12 is a plan view illustrating an integrated circuit 30, according to an embodiment. FIG. 13 is a perspective view illustrating the integrated circuit 30 of FIG. 12, according to an embodiment.

Referring to FIGS. 12 and 13 together, the integrated circuit 30 may include first metal lines 31a and 31b, second metal lines 33a and 33b, a first conductive line 32, and a second conductive line 34. The first metal lines 31a and 31b, the first conductive line 32, the second metal lines 33a and 33b, and the second conductive line 34 may be disposed on a same layer. For example, the first metal lines 31a and 31b, the first conductive line 32, the second metal lines 33a and 33b, and the second conductive line 34 may have heights in the vertical direction Z that may be substantially similar and/or may be the same height. Alternatively or additionally, the first metal lines 31a and 31b, the first conductive line 32, the second metal lines 33a and 33b, and the second conductive line 34 may have upper surfaces with levels that may be substantially similar and/or may be the same level. In an optional or additional embodiment, the first metal lines 31a and 31b, the first conductive line 32, the second metal lines 33a and 33b, and the second conductive line 34 may have lower surfaces with levels that may be substantially similar and/or may be the same level.

In an embodiment, the first metal lines 31a and 31b may be connected to the first conductive line 32 to form the first node NODE_A. Alternatively or additionally, the second metal lines 33a and 33b may be connected to the second conductive line 34 to form the second node NODE_B. In an embodiment, a first voltage may be applied to the first node NODE_A. Alternatively or additionally, a second voltage may be applied to the second node NODE_B. In an optional or additional embodiment, the voltage level of the first voltage may be different from the voltage level of the second voltage. For example, the first voltage may correspond to the power voltage, and the second voltage may correspond to the ground voltage. Alternatively or additionally, the first voltage may correspond to the ground voltage and the second voltage may correspond to the power voltage. That is, the present disclosure may not be limited in this regard.

An insulating material, a dielectric material and/or a dielectric layer (not shown) may be disposed between the first metal lines 31a and 31b and the first conductive line 32 and between the second metal lines 33a and 33b and the second conductive line 34. As a result, the first and second metal lines 31a, 31b, 33a, and 33b and the first and second conductive lines 32 and 34, together with the dielectric layer, may constitute a capacitor structure (e.g., a MIM capacitor).

In an embodiment, each of the first and second metal lines 31a, 31b, 33a, and 33b may extend in the first horizontal direction X. In an optional or additional embodiment, each of the first and second conductive lines 32 and 34 may extend in the second horizontal direction Y. For example, the first and second conductive lines 32 and 34 may have widths in the first horizontal direction X that may be substantially similar and/or may be the same width. However, the present disclosure may not be limited in this regard.

In an embodiment, a surface (e.g., a side surface) of each of the first and second metal lines 31a, 31b, 33a, and 33b may have a semicircular pattern. That is, at least one surface of each of the first metal lines 31a and 31b may have a first semicircular pattern, and/or at least one surface of each of the second metal lines 33a and 33b may have a second semicircular pattern. For example, the first semicircular pattern and the second semicircular pattern may have an engagement (e.g., interlocking) structure. In an embodiment, the first semicircular pattern may be substantially similar and/or may be the same as the second semicircular pattern. Accordingly, the first and second metal lines 31a, 31b, 33a, and 33b may be formed using a same mask.

In an embodiment, when the at least one surface of each of the first and second metal lines 31a, 31b, 33a, and 33b has the semicircular pattern, a surface area of each of the first and second metal lines 31a, 31b, 33a, and 33b may be significantly increased compared to a surface area of comparable metal lines that have a substantially flat surface. Accordingly, a capacitance of the capacitor structure (e.g., a MIM capacitor) configured by the first and second metal lines 31a, 31b, 33a, and 33b may be greater than a capacitance of another capacitor structure using the metal lines having the substantially flat surfaces.

According to an embodiment, each of the first metal lines 31a and 31b may have a first patterned side surface having the semicircular pattern. Alternatively or additionally, each of the second metal lines 33a and 33b may have a second patterned side surface having the semicircular pattern. However, the present disclosure may not be limited in this regard. For example, the first metal line may have a first flat side surface, and the second metal line may have a second flat side surface. Consequently, the surface area of each of the first and second patterned side surfaces may be greater than the surface area of each of the first and second flat side surfaces. For example, the surface area of each of the first and second patterned side surfaces may correspond to approximately 1.57 times the surface area of each of the first and second flat side surfaces.

In an embodiment, the first and second metal lines 31a and 33a may be spaced apart from each other by a third space S3 in the second horizontal direction Y. In an optional or additional embodiment, each of the first and second metal lines 31a and 33a may have a third width W3 in the second horizontal direction Y. Alternatively or additionally, the first and second metal lines 31a, 31b, 33a, and 33b may have different widths in the second horizontal direction Y. That is, the third space S3 and/or the third width W3 may be changed in various ways according to embodiments and/or design constraints implemented on the integrated circuit 30.

In an embodiment, at least one surface of each of the first and second metal lines 31a, 31b, 33a, and 33b may have a semicircular pattern in which each semicircular shape in the semicircular pattern may have a diameter D. The diameter D may be changed in various ways according to embodiments and/or design constraints implemented on the integrated circuit 30. For example, the diameter D may be smaller than approximately 26 nm. However, the present disclosure may not be limited in this regard. In an optional or additional embodiment, the third space S3 and/or the third width W3 may increase as the diameter D is increased, and, thus, the capacitance of the MIM capacitor structure may increase.

In an embodiment, the first and second surfaces of the first metal line 31a facing each other may have a semicircular pattern. Alternatively or additionally, the first and second surfaces of the second metal line 33a facing each other may have a semicircular pattern. In an optional or additional embodiment, the second surface of the first metal line 31a and the first surface of the second metal line 33a may face each other. For example, a semicircular protrusion on the second surface of the first metal line 31a may be spaced apart from a semicircular protrusion on the first surface of the second metal line 33a by a third distance D3. That is, the third distance D3 may correspond to the length obtained by subtracting the diameter D of the first semicircular pattern from a distance between the center of the first semicircular pattern on the first metal line 31a and the center of the second semicircular pattern on the second metal line 33a. The third distance D3 may be changed in various ways according to embodiments and/or design constraints implemented on the integrated circuit 30.

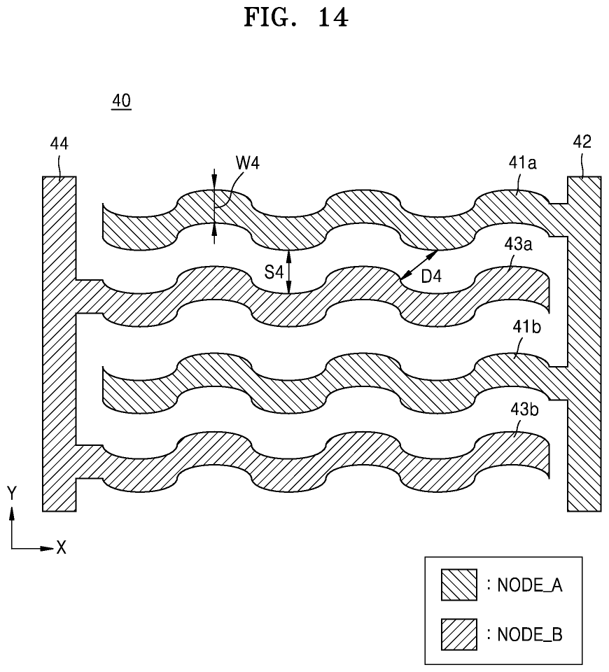

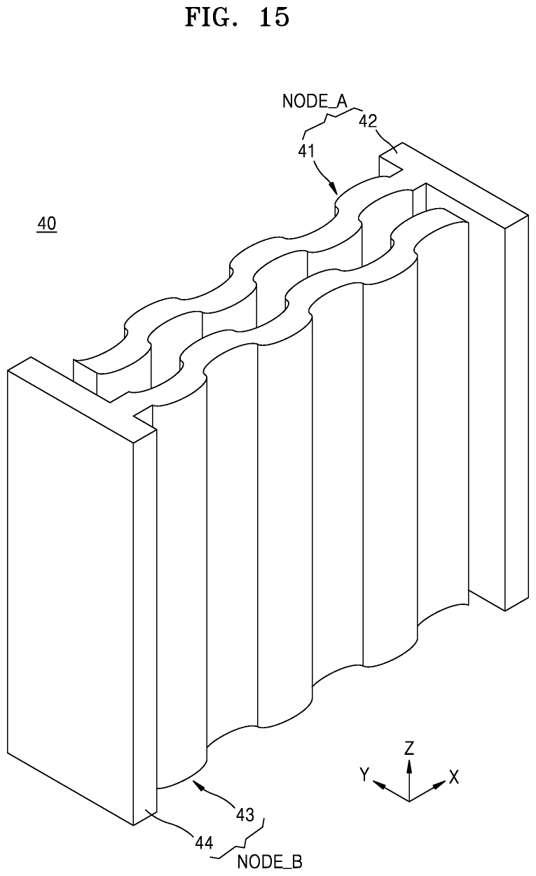

FIG. 14 is a plan view illustrating an integrated circuit 40, according to an embodiment. FIG. 15 is a perspective view illustrating the integrated circuit 40 of FIG. 14, according to an embodiment.

Referring to FIGS. 14 and 15 together, the integrated circuit 40 may include first metal lines 41a and 41b, second metal lines 43a and 43b, a first conductive line 42, and a second conductive line 44. The first metal lines 41a and 41b, the first conductive line 42, the second metal lines 43a and 43b, and the second conductive line 44 may be disposed on a same layer. For example, the first metal lines 41a and 41b, the second metal lines 43a and 43b, the first conductive line 42, and the second conductive line 44 may have heights in the vertical direction Z that may be substantially similar and/or may be the same height. Alternatively or additionally, the first metal lines 41a and 41b, the second metal lines 43a and 43b, the first conductive line 42, and the second conductive line 44 may have upper surfaces with levels that may be substantially similar and/or may be the same level. In an optional or additional embodiment, the first metal lines 41a and 41b, the second metal lines 43a and 43b, the first conductive line 42, and the second conductive line 44 may have lower surfaces with levels that may be substantially similar and/or may be the same level.

In an embodiment, the first metal lines 41a and 41b may be connected to the first conductive line 42 to form the first node NODE_A. In an optional or additional embodiment, the second metal lines 43a and 43b may be connected to the second conductive line 44 to form the second node NODE_B. In an embodiment, a first voltage may be applied to the first node NODE_A. Alternatively or additionally, a second voltage may be applied to the second node NODE_B. In an optional or additional embodiment, the voltage level of the first voltage may be different from the voltage level of the second voltage. For example, the first voltage may correspond to the power voltage, and the second voltage may correspond to the ground voltage. Alternatively or additionally, the first voltage may correspond to the ground voltage and the second voltage may correspond to the power voltage. That is, the present disclosure may not be limited in this regard.

An insulating material, a dielectric material and/or a dielectric layer (not shown) may be disposed between the first metal lines 41a and 41b and the first conductive line 42 and between the second metal lines 43a and 43b and the second conductive line 44. Accordingly, the first and second metal lines 41a, 41b, 43a, and 43b and the first and second conductive lines 42 and 44, together with the dielectric layer, may constitute a capacitor structure (e.g., a MIM capacitor).

In an embodiment, each of the first and second metal lines 41a, 41b, 43a, and 43b may extend in the first horizontal direction X. In an optional or additional embodiment, each of the first and second conductive lines 42 and 44 may extend in the second horizontal direction Y. For example, the first and second conductive lines 42 and 44 may have a substantially similar and/or the same width in the first horizontal direction X. Alternatively or additionally, the first and second conductive lines 42 and 44 may have different widths in the first horizontal direction X. That is, the present disclosure may not be limited in this regard.

In an embodiment, at least one surface of each of the first and second metal lines 41a, 41b, 43a, and 43b may have a semielliptical pattern and/or a wave pattern. For example, a surface of each of the first metal lines 41a and 41b may have a first semielliptical pattern, and a surface of each of the second metal lines 43a and 43b may have a second semielliptical pattern. In an embodiment, the first semielliptical pattern may be substantially similar and/or the same as the second semielliptical pattern in the diameter of the major direction and/or the length of the major axis. Alternatively or additionally, the first semielliptical pattern and the second semielliptical pattern may have an engagement (e.g., interlocking) structure. In an optional or additional embodiment, the first semielliptical pattern may be substantially similar and/or the same as the second semielliptical pattern in the diameter of the minor direction and/or the length of the minor axis. Alternatively or additionally, the first semielliptical pattern and the second semielliptical pattern may have an engagement (e.g., interlocking) structure. In another optional or additional embodiment, the first and second metal lines 41a, 41b, 43a, and 43b may have heights, upper surface levels, and/or lower surface levels that may be substantially similar and/or may be the same, respectively. Accordingly, in such an embodiment, the first and second metal lines 41a, 41b, 43a, and 43b may be formed using a same mask.

In an embodiment, when the surface of each of the first and second metal lines 41a, 41b, 43a, and 43b has the semielliptical pattern and/or the wave pattern, a surface area of each of the first and second metal lines 41a, 41b, 43a, and 43b may be significantly increased compared to a surface area of comparable first and second metal lines that may have a substantially flat surface. Accordingly, the capacitance of the capacitor structure (e.g., a MIM capacitor) configured by the first and second metal lines 41a, 41b, 43a, and 43b may be greater than the capacitance of another capacitor structure using the metal lines having the substantially flat surfaces.

In an embodiment, the first and second metal lines 41a and 43a may be spaced apart from each other by a fourth space S4 in the second horizontal direction Y. In an optional or additional embodiment, each of the first and second metal lines 41a and 43a may have a fourth width W4 in the second horizontal direction Y. Alternatively or additionally, the first and second metal lines 41a, 41b, 43a, and 43b may have different widths in the second horizontal direction Y. That is, the fourth space S4 and/or the fourth width W4 may be changed in various ways according to embodiments and/or design constraints implemented on integrated circuit 40.

In an embodiment, the first and second surfaces of the first metal line 41a facing each other may have a semielliptical pattern and/or a wave pattern. In an optional or additional embodiment, the first and second surfaces of the second metal line 43a facing each other may have a semielliptical pattern and/or a wave pattern. Alternatively or additionally, the second surface of the first metal line 41a and the first surface of the second metal line 43a may face each other. For example, a semielliptical protrusion on the second surface of the first metal line 41a may be spaced apart from a semielliptical protrusion on the first surface of the second metal line 43a by a fourth distance D4. It is to be understood that the fourth distance D4 may be changed in various ways according to embodiments and/or design constraints implemented on the integrated circuit 40.

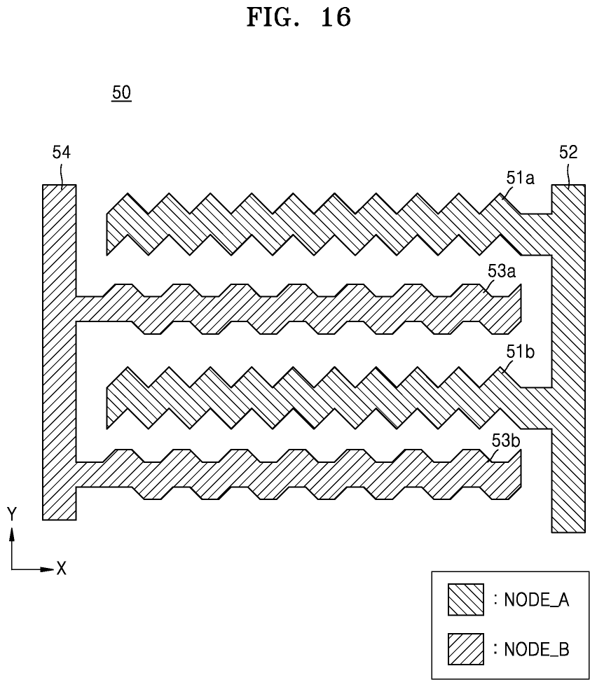

FIG. 16 is a plan view illustrating an integrated circuit 50, according to an embodiment.

Referring to FIG. 16, the integrated circuit 50 may include first metal lines 51a and 51b, second metal lines 53a and 53b, a first conductive line 52, and a second conductive line 54. In an embodiment, the first metal lines 51a and 51b, the first conductive line 52, the second metal lines 53a and 53b, and the second conductive line 54 may be disposed on a same layer. For example, the first metal lines 51a and 51b, the second metal lines 53a and 53b, the first conductive line 52, and the second conductive line 54 may have heights in the vertical direction Z that may be the substantially similar and/or may be the same height. Alternatively or additionally, the first metal lines 51a and 51b, the second metal lines 53a and 53b, the first conductive line 52, and the second conductive line 54 may have upper surfaces with levels that may be substantially similar and/or may be the same level. In an optional or additional embodiment, the first metal lines 51a and 51b, the second metal lines 53a and 53b, the first conductive line 52, and the second conductive line 54 may have lower surfaces with levels that may be substantially similar and/or may be the same level.

In an embodiment, the first metal lines 51a and 51b may be connected to the first conductive line 52 to form the first node NODE_A. In an optional or additional embodiment, the second metal lines 53a and 53b may be connected to the second conductive line 54 to form the second node NODE_B. In an embodiment, a first voltage may be applied to the first node NODE_A. Alternatively or additionally, a second voltage may be applied to the second node NODE_B. In an optional or additional embodiment, the voltage level of the first voltage may be different from the voltage level of the second voltage. For example, the first voltage may correspond to the power voltage, and the second voltage may correspond to the ground voltage. Alternatively or additionally, the first voltage may correspond to the ground voltage and the second voltage may correspond to the power voltage. That is, the present disclosure may not be limited in this regard.

An insulating material, a dielectric material, and/or a dielectric layer may be disposed between the first metal lines 51a and 51b and the first conductive line 52 and between the second metal lines 53a and 53b and the second conductive line 54. Accordingly, the first and second metal lines 51a, 51b, 53a, and 53b and the first and second conductive lines 52 and 54, together with the dielectric layer, may constitute a capacitor structure (e.g., a MIM capacitor).

In an embodiment, each of the first and second metal lines 51a, 51b, 53a, and 53b may extend in the first horizontal direction X. In an optional or additional embodiment, each of the first and second conductive lines 52 and 54 may extend in the second horizontal direction Y. For example, the first and second conductive lines 52 and 54 may have widths in the first horizontal direction X that may be substantially similar and/or may be the same width. Alternatively or additionally, the first and second conductive lines 52 and 54 may have different widths in the first horizontal direction X. That is, the present disclosure may not be limited in this regard.

In an embodiment, at least one surface of each of the first metal lines 51a and 51b may have a first pattern. Alternatively or additionally, at least one surface of each of the second metal lines 53a and 53b may have a second pattern. In an optional or additional embodiment, the first pattern and the second pattern may be implemented in different shapes. For example, the first pattern may be a saw pattern and the second pattern may be a polygonal pattern. However, the present disclosure may not be limited in this regard. For example, the first pattern may be one of a saw pattern, a polygonal pattern, a semicircular pattern, and a semielliptical pattern, and the second pattern may be another one of the saw pattern, the polygonal pattern, the semicircular pattern, and the semielliptical pattern.

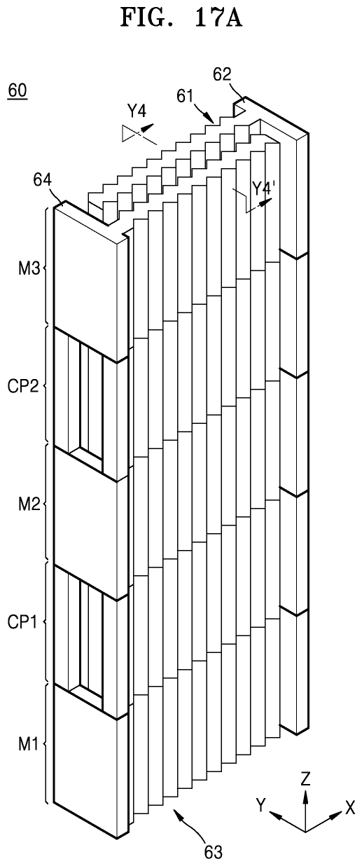

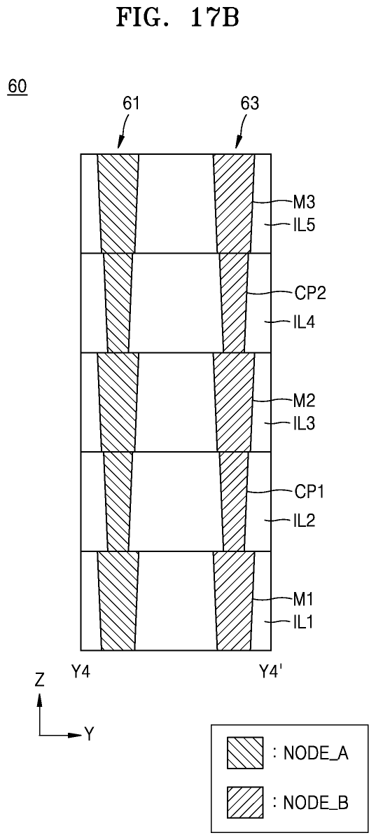

FIG. 17A is a perspective view illustrating an integrated circuit 60, according to an embodiment. FIG. 17B is a cross-sectional view taken along a line Y4-Y4′ of FIG. 17A, according to an embodiment.

Referring to FIGS. 17A and 17B together, the integrated circuit 60 may include a first metal line 61, a first conductive line 62, a second metal line 63, and a second conductive line 64. In an embodiment, the first metal line 61, the first conductive line 62, the second metal line 63, and the second conductive line 64 may be implemented in a wall type, and may constitute, together with the dielectric layers IL1 to IL5, a wall-type capacitor structure (e.g., a wall-type MIM capacitor).

In an embodiment, the first metal line 61 may include the first metal layer M1, the first contact CP1, the second metal layer M2, the second contact CP2, and the third metal layer M3. Alternatively or additionally, each of the first metal layer M1, the first contact CP1, the second metal layer M2, the second contact CP2, and the third metal layer M3 may extend in the first horizontal direction X. In an optional or additional embodiment, the surface of each of the first metal layer M1, the first contact CP1, the second metal layer M2, the second contact CP2, and the third metal layer M3 may have a pattern extending in the vertical direction Z. In another optional or additional embodiment, the first metal layer M1, the second metal layer M2, and the third metal layer M3 of the first metal line 61 may be connected to the first conductive line 62, and the first and second contacts CP1 and CP2 of the first metal line 61 may not be connected to the first conductive line 62.

In an embodiment, the second metal line 63 may include the first metal layer M1, the first contact CP1, the second metal layer M2, the second contact CP2, and the third metal layer M3. Alternatively or additionally, each of the first metal layer M1, the first contact CP1, the second metal layer M2, the second contact CP2, and the third metal layer M3 may extend in the first horizontal direction X. In an optional or additional embodiment, the surface of each of the first metal layer M1, the first contact CP1, the second metal layer M2, the second contact CP2, and the third metal layer M3 may have a pattern extending in the vertical direction Z. In another optional or additional embodiment, the first metal layer M1, the second metal layer M2, and the third metal layer M3 of the second metal line 63 may be connected to the second conductive line 64, and the first and second contacts CP1 and CP2 of the second metal line 63 may not be connected to the second conductive line 64. In some embodiments, the surface of each of the first and second conductive lines 62 and 64 may have a pattern extending in the vertical direction Z.

In an embodiment, the first conductive line 62 may include the first to third metal layers M1, M2, and M3 extending in the second horizontal direction Y. In an optional or additional embodiment, the first conductive line 62 may include a plurality of first contacts CP1 between the first and second metal layers M1 and M2 and a plurality of second contacts CP2 between the second and third metal layers M2 and M3. Alternatively or additionally, the second conductive line 64 may include the first to third metal layers M1, M2, and M3 extending in the second horizontal direction Y, and may include the plurality of first contacts CP1 between the first and second metal layers M1 and M2 and the plurality of second contacts CP2 between the second and third metal layers M2 and M3. However, the present disclosure may not be limited in this regard. For example, in some embodiments, the respective first and second contacts CP1 and CP2 of the first and second conductive lines 62 and 64 may also extend in the second horizontal direction Y. In optional or additional embodiments, at least one of the first to third metal layers M1, M2, or M3 of each of the first and second conductive lines 62 and 64 may be implemented as a plurality of metal patterns extending in the vertical direction Z.

In some embodiments, each of the first and second metal lines 61 and 63 may include the first metal layer M1, the first contact CP1, the second metal layer M2, the second contact CP2, and the third metal layer M3, and each of the first and second conductive lines 62 and 64 may include the first metal layer M1, the second metal layer M2, and a third metal layer M3. Alternatively or additionally, each of the first and second conductive lines 62 and 64 may include the first metal layer M1, one first contact CP1, one second metal layer M2, one second contact CP2, and the third metal layer M3.

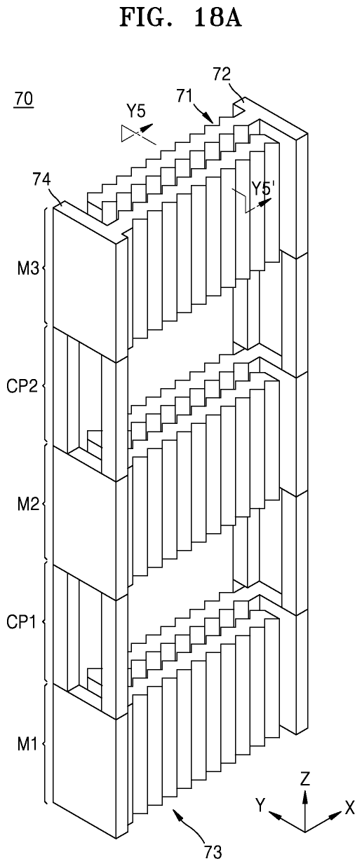

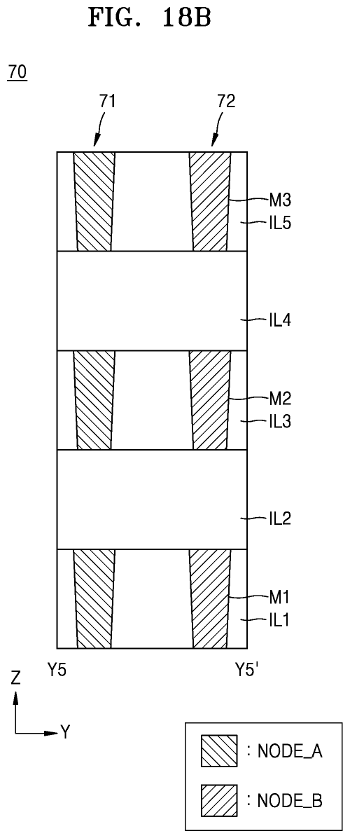

FIG. 18A is a perspective view illustrating an integrated circuit 70, according to an embodiment. FIG. 18B is a cross-sectional view taken along a line Y5-Y5′ of FIG. 18A, according to an embodiment.

Referring to FIGS. 18A and 18B together, the integrated circuit 70 may include a first metal line 71, a first conductive line 72, a second metal line 73, and a second conductive line 74. In an embodiment, the first metal line 71, the first conductive line 72, the second metal line 73, and the second conductive line 74 may be implemented in a wall type, and may constitute, together with the dielectric layers IL1 to IL5, a wall-type capacitor structure (e.g., a wall-type MIM capacitor).

In an embodiment, the first metal line 71 may include the first metal layer M1, the second metal layer M2, and the third metal layer M3. Alternatively or additionally, each of the first metal layer M1, the second metal layer M2, and the third metal layer M3 may extend in the first horizontal direction X, and the surface of each of the first metal layer M1, the second metal layer M2, and the third metal layer M3 may have a pattern extending in the vertical direction Z. In an optional or additional embodiment, the first metal layer M1, the second metal layer M2, and the third metal layer M3 of the first metal line 71 may be connected to the first conductive line 72.

In an embodiment, the second metal line 73 may include the first metal layer M1, the second metal layer M2, and the third metal layer M3. Alternatively or additionally, each of the first metal layer M1, the second metal layer M2, and the third metal layer M3 may extend in the first horizontal direction X, and the surface of each of the first metal layer M1, the second metal layer M2, and the third metal layer M3 may have a pattern extending in the vertical direction Z. In an optional or additional embodiment, the first metal layer M1, the second metal layer M2, and the third metal layer M3 of the second metal line 73 may be connected to the second conductive line 74. In some embodiments, the surface of each of the first and second conductive lines 72 and 74 may have a pattern extending in the vertical direction Z.

In an embodiment, the first conductive line 72 may include the first to third metal layers M1, M2, and M3 extending in the second horizontal direction Y, and may include a plurality of first contacts CP1 between the first and second metal layers M1 and M2 and a plurality of second contacts CP2 between the second and third metal layers M2 and M3. Alternatively or additionally, the second conductive line 74 may include the first to third metal layers M1, M2, and M3 extending in the second horizontal direction Y, and may include the plurality of first contacts CP1 between the first and second metal layers M1 and M2 and the plurality of second contacts CP2 between the second and third metal layers M2 and M3. However, the present disclosure may not be limited in this regard. For example, in some embodiments, the respective first and second contacts CP1 and CP2 of the first and second conductive lines 72 and 74 may also extend in the second horizontal direction Y. In optional or additional embodiments, at least one of the first to third metal layers M1, M2, or M3 of each of the first and second conductive lines 72 and 74 may be implemented as a plurality of metal patterns extending in the vertical direction Z. Alternatively or additionally, each of the first and second conductive lines 72 and 74 may include the first metal layer M1, one first contact CP1, one second metal layer M2, one second contact CP2, and the third metal layer M3.

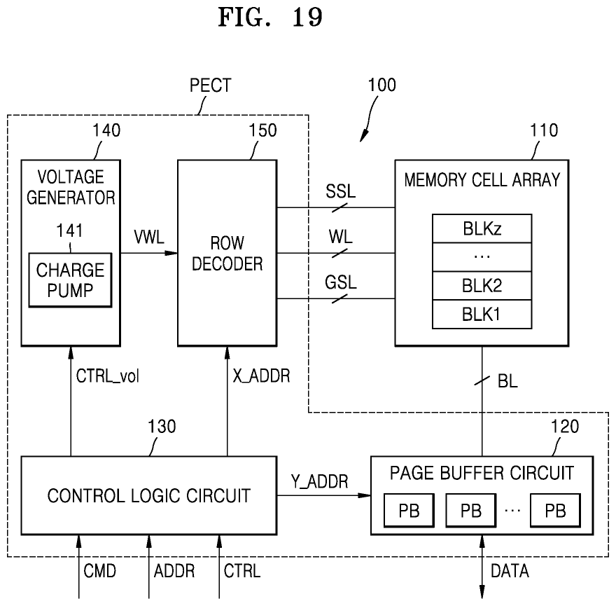

FIG. 19 is a block diagram illustrating a memory device 100, according to an embodiment.

Referring to FIG. 19, the memory device 100 may include a memory cell array 110 and a peripheral circuit PECT. The peripheral circuit PECT may include a page buffer circuit 120, a control logic circuit 130, a voltage generator 140, and a row decoder 150. In some embodiments, the peripheral circuit PECT may further include a data input/output circuit and/or an input/output interface (not shown). Alternatively or additionally, the peripheral circuit PECT may further include a temperature sensor, a command decoder, an address decoder, and the like (not shown). In some embodiments, the memory device 100 may include a non-volatile memory device and, as such, may be referred to as a non-volatile memory device.

The memory cell array 110 may include a plurality of memory blocks BLK1 to BLKz (hereinafter “BLK”, generally), where z is a positive integer greater than zero (0). In an embodiment, each of the plurality of memory blocks BLK may include a plurality of memory cells. The memory cell array 110 may be connected to the page buffer circuit 120 through bit lines BL. Alternatively or additionally, the memory cell array 110 may be connected to the row decoder 150 through word lines WL, string selection lines SSL, and ground selection lines GSL. For example, the memory cells may include flash memory cells. Hereinafter, some embodiments in which the memory cells include NAND flash memory cells may be described. However, the present disclosure may not be limited in this regard. For example, in some embodiments, the memory cells may include resistive memory cells such as, but not be limited to, resistive RAM (ReRAM), phase change RAM (PRAM), and/or magnetic RAM (MRAM).

In an embodiment, the memory cell array 110 may include a three-dimensional (3D) memory cell array. The 3D memory cell array may include a plurality of NAND strings. Each NAND string may include memory cells respectively connected to word lines vertically stacked on a substrate, described with reference to FIG. 2. U.S. Pat. Nos. 7,679,133, 8,553,466, 8,654,587, 8,559,235, and 9,536,970 disclose suitable configurations of a 3D memory cell array including a plurality of levels and having word lines and/or bit lines shared between the levels, the disclosures of which are incorporated by reference herein in their entireties. However, the present disclosure may not be limited in this regard. For example, in some embodiments, the memory cell array 110 may include a two-dimensional (2D) memory cell array. The 2D memory cell array may include a plurality of NAND strings disposed in row and column directions.

The page buffer circuit 120 may include a plurality of page buffers PB. The plurality of page buffers PB may be respectively connected to memory cells of the memory cell array 110 through corresponding bit lines BL. The page buffer circuit 120 may select at least one of the bit lines BL under the control by the control logic circuit 130. For example, the page buffer circuit 120 may select some of the bit lines BL in response to a column address Y_ADDR received from the control logic circuit 130. Each of the plurality of page buffers PB may operate as a write driver and/or a sense amplifier. For example, in a program operation, each of the plurality of page buffers PB may apply a voltage corresponding to data DATA to be programmed to a bit line BL and store the data DATA in a memory cell. For another example, in a program verify operation and/or a read operation, each of the plurality of page buffers PB may sense a current and/or voltage through a bit line BL and sense the programmed data DATA.

The control logic circuit 130 may output various control signals, such as, but not limited to, a voltage control signal CTRL_vol, a row address X_ADDR, and a column address Y_ADDR. The control logic circuit 130 may use the control signals for programming data into the memory cell array 110, reading data from the memory cell array 110, and/or erasing data stored in the memory cell array 110 based on a command CMD, an address ADDR, and a control signal CTRL. Accordingly, the control logic circuit 130 may control various operations within the memory device 100. In some embodiments, the control logic circuit 130 may receive the command CMD, the address ADDR, and the control signal CTRL from a memory controller.

The voltage generator 140 may generate various types of voltages for performing program, read, and/or erase operations on the memory cell array 110, based on the voltage control signal CTRL_vol. That is, the voltage generator 140 may generate a word line voltage VWL, which may include, but not be limited to, a program voltage, a read voltage, a pass voltage, an erase verify voltage, and/or a program verify voltage. Alternatively or additionally, the voltage generator 140 may generate a string selection line voltage and/or a ground selection line voltage, based on the voltage control signal CTRL_vol.

The voltage generator 140 may include a charge pump 141. The charge pump 141 may provide a high current to apply voltage to the word lines WL. The charge pump 141 may include a plurality of capacitors that may accumulate charges. In an embodiment, the accumulated charges may be provided to the word lines WL of the memory cell array 110 through the row decoder 150.

In an embodiment, the charge pump 141 may include at least one of the capacitor structures described above with reference to FIGS. 1 to 18B (e.g., the MIM capacitor and/or the integrated circuits 10, 10a, 10b, 10c, 10d, 20, 30, 40, 50, 60, and/or 70). As the number of word lines WL stacked on the substrate in the memory device 100 increases, the size of the memory device 100 may decrease, and accordingly, an increase in the capacity of the charge pump 141 included in the peripheral circuit PECT may be needed.

For example, in the capacitor structures and/or the integrated circuits shown in FIGS. 1 to 18B (e.g., 10, 10a, 10b, 10c, 10d, 20, 30, 40, 50, 60, and 70), the capacitance of the MIM capacitor configured by the dielectric layer and the first metal lines (e.g., 11, 11a, 11b, 21, 31, 41, 51, 61, and 71) and the second metal lines (e.g., 13, 13a, 13b, 23, 33, 43, 53, 63, and 73) may increase when the surfaces of the first metal lines and the second metal lines disposed on the same level are patterned. That is, when the side surfaces of the first metal lines and the second metal lines have patterns extending in the vertical direction, the surface area of an electrode constituting a MIM capacitor may increase when compared to another capacitor using a flat surface, and accordingly, the capacitance of the MIM capacitor may increase. Therefore, the charge pump 141 may provide a capacitance greater than that of a related capacitor having a similar size that uses a flat surface.

The row decoder 150 may select one of the plurality of memory blocks BLK in response to the row address X_ADDR received from the control logic circuit 130, select one of the word lines WL of the selected memory block, and select one of the string selection lines SSL. For example, in a program operation, the row decoder 150 may apply a program voltage and/or a program verify voltage to the selected word line. For another example, in a read operation, the row decoder 150 may apply a read voltage to the selected word line.

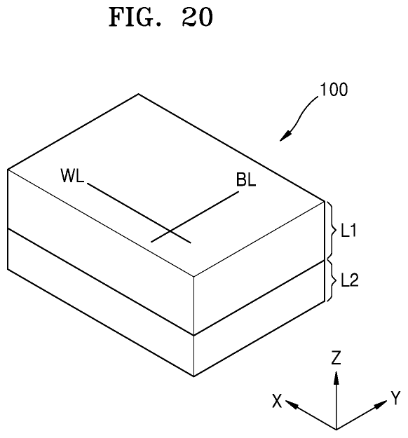

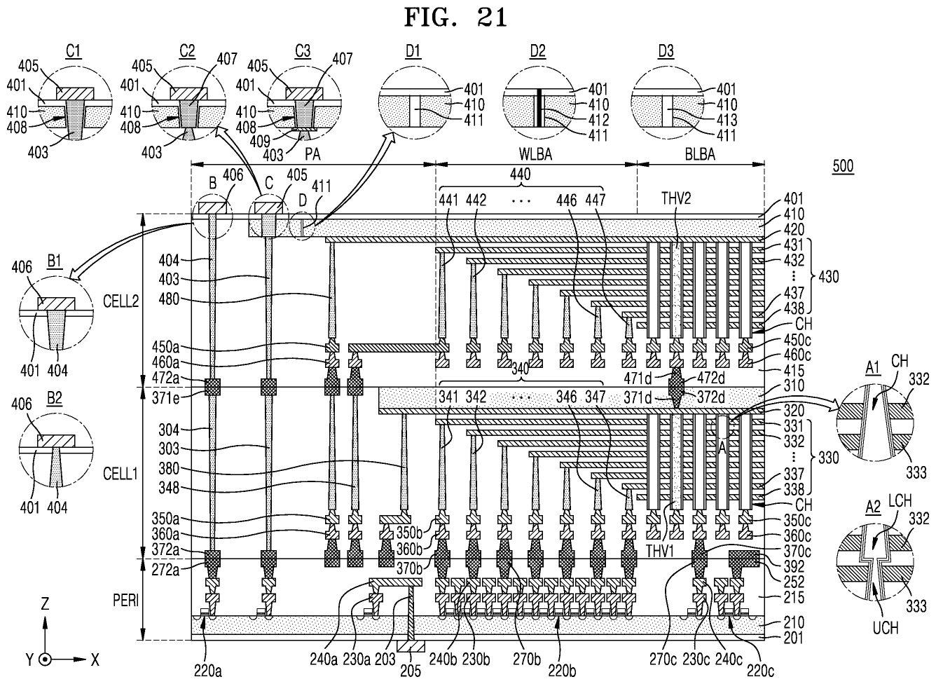

According to an embodiment, the memory cell array 110 may be disposed on a first semiconductor layer L1 of FIG. 20 and/or CELL1 or CELL2 of FIG. 21. Alternatively or additionally, the peripheral circuit PECT may be disposed on a second semiconductor layer L2 in FIG. 20 and/or a peripheral circuit region PERI in FIG. 21. In some embodiments, at least a part of the peripheral circuit PECT may overlap the memory cell array 110 in the vertical direction.

FIG. 20 schematically illustrates a structure of a memory device 100 according to an embodiment.

Referring to FIGS. 19 and 20 together, the memory device 100 may include the first semiconductor layer L1 and the second semiconductor layer L2. In an embodiment, the first semiconductor layer L1 may be stacked on the second semiconductor layer L2 in the vertical direction Z. That is, the second semiconductor layer L2 may be disposed below the first semiconductor layer L1 in the vertical direction Z. In an optional or additional embodiment, the memory cell array 110 may be formed on the first semiconductor layer L1 and the peripheral circuit PECT may be formed on the second semiconductor layer L2. Accordingly, the memory device 100 may have a structure in which the memory cell array 110 may be disposed above the peripheral circuit PECT, such as, but not limited to, a cell over periphery (COP) structure and/or a bonding vertical NAND (VNAND) (B-VNAND) structure.

In the first semiconductor layer L1, the plurality of bit lines BL may extend in the first direction Y, and the plurality of word lines WL may extend in the second direction X. Alternatively or additionally, the plurality of bit lines BL may extend in the second direction X, and the plurality of word lines WL may extend in the first direction Y. That is, the present disclosure may not be limited in this regard.

In an embodiment, the second semiconductor layer L2 may include a substrate, and the peripheral circuit PECT may be formed on the second semiconductor layer L2 by forming semiconductor devices such as, but not limited to, transistors and patterns for wiring the devices on the substrate.

In an embodiment, when the memory device 100 has the COP structure, the peripheral circuit PECT may be formed on the second semiconductor layer L2. Subsequently, the first semiconductor layer L1, including the memory cell array 110, may be formed, and patterns may be formed to electrically connect the word lines WL and bit lines BL of the memory cell array 110 and the peripheral circuit PECT formed on the second semiconductor layer L2. In an optional or additional embodiment, when the memory device 100 has the B-VNAND structure, the peripheral circuit PECT and lower bonding pads may be formed on the second semiconductor layer L2, and the memory cell array 110 and upper bonding pads may be formed on the first semiconductor layer L1. Subsequently, the upper bonding pads on the first semiconductor layer L1 and the lower bonding pads on the second semiconductor layer L2 may be connected by bonding.

FIG. 21 is a view illustrating a memory device 500, according to some embodiments.

Referring to FIG. 21, the memory device 500 may have a chip-to-chip (C2C) structure. The C2C structure may refer to a structure obtained by connecting at least one upper chip including a cell region and a lower chip including a peripheral circuit region PERI to each other by using a bonding method after separately manufacturing the at least one upper chip including the cell region and the lower chip including the peripheral circuit region PERI. Alternatively or additionally, the bonding method may refer to a method of electrically and/or physically connecting a bonding metal pattern formed in an uppermost metal layer of the upper chip to a bonding metal pattern formed in an uppermost metal layer of the lower chip to each other. For example, when the bonding metal patterns are formed of copper (Cu), the bonding method may be a Cu—Cu bonding method. Alternatively or additionally, the bonding metal patterns may be formed of aluminum (Al) and/or tungsten (W). However, the present disclosure is not limited in this regard.

The memory device 500 may include the at least one upper chip including the cell region. For example, as shown in FIG. 21, the memory device 500 may include two upper chips. However, the number of the upper chips may not be limited in this regard. For example, when the memory device 500 includes the two (2) upper chips, a first upper chip including a first cell region CELL1, a second upper chip including a second cell region CELL2 and the lower chip including the peripheral circuit region PERI may be manufactured separately, and the first upper chip, the second upper chip and the lower chip may be connected to each other by the bonding method to manufacture the memory device 500.

In an embodiment, the first upper chip may be turned over and connected to the lower chip by the bonding method. Alternatively or additionally, the second upper chip may be turned over and connected to the first upper chip by the bonding method. Hereinafter, upper and lower portions of each of the first and second upper chips may be referred to based on orientations of the first and second upper chips before each of the first and second upper chips have been turned over. That is, an upper portion of the lower chip may refer to an upper portion based on a +Z-axis direction, and the upper portion of each of the first and second upper chips may refer to an upper portion defined based on a −Z-axis direction in FIG. 21. However, the present disclosure may not be limited in this regard. In certain embodiments, one of the first upper chip and the second upper chip may be turned over and then may be connected to a corresponding chip by the bonding method.

In the memory device 500, each of the peripheral circuit region PERI and the first and second cell regions CELL1 and CELL2 may include an external pad bonding region PA, a word line bonding region WLBA, and a bit line bonding region BLBA.

The peripheral circuit region PERI may include a first substrate 210 and a plurality of circuit elements (e.g., 220a, 220b and 220c) formed on the first substrate 210. An interlayer insulating layer 215 including one or more insulating layers may be provided on the plurality of circuit elements 220a, 220b and 220c. A plurality of metal lines electrically connected to the plurality of circuit elements 220a, 220b and 220c may be provided in the interlayer insulating layer 215. For example, the plurality of metal lines may include first metal lines 230a, 230b and 230c connected to the plurality of circuit elements 220a, 220b and 220c, and second metal lines 240a, 240b and 240c formed on the first metal lines 230a, 230b and 230c. The plurality of metal lines may be formed of at least one of various conductive materials. For example, the first metal lines 230a, 230b and 230c may be formed of a material having a relatively high electrical resistivity, such as, but not limited to, tungsten (W). Alternatively or additionally, the second metal lines 240a, 240b and 240c may be formed of a material having a relatively low electrical resistivity, such as, but not limited to, copper (Cu).

The first metal lines 230a, 230b and 230c and the second metal lines 240a, 240b and 240c may include and/or may be similar in many respects to the first and second metal lines described above with reference to FIGS. 1 to 18B, and may include additional features not mentioned above. For example, in certain embodiments, at least one or more additional metal lines may further be formed on the second metal lines 240a, 240b and 240c. In such embodiments, the second metal lines 240a, 240b and 240c may be formed of aluminum (Al), and at least some of the additional metal lines formed on the second metal lines 240a, 240b and 240c may be formed of copper (Cu) having an electrical resistivity lower than that of the aluminum (Al) of the second metal lines 240a, 240b and 240c.

The interlayer insulating layer 215 may be disposed on the first substrate 210 and may include, but not be limited to, an insulating material such as silicon oxide (SiO) and/or silicon nitride (Si₃N₄).

Each of the first and second cell regions CELL1 and CELL2 may include at least one memory block. The first cell region CELL1 may include a second substrate 310 and a common source line 320. A plurality of word lines 330 (e.g., 331 to 338) may be stacked on the second substrate 310 in a direction (e.g., the vertical direction Z) perpendicular to a top surface of the second substrate 310. String selection lines and a ground selection line may be disposed on and/or under the plurality of word lines 330. The plurality of word lines 330 may be disposed between the string selection lines and the ground selection line. In a similar manner, the second cell region CELL2 may include a third substrate 410 and a common source line 420, and a plurality of word lines 430 (e.g., 431 to 438) may be stacked on the third substrate 410 in a direction (e.g., the vertical direction Z) perpendicular to a top surface of the third substrate 410. Each of the second substrate 310 and the third substrate 410 may be formed of at least one of various materials such as, but not limited to, a silicon substrate, a silicon-germanium substrate, a germanium substrate, and/or a substrate having a single-crystalline epitaxial layer grown on a single-crystalline silicon substrate. A plurality of channel structures CH may be formed in each of the first and second cell regions CELL1 and CELL2.

In some embodiments, as shown in a region A1, the channel structure CH may be provided in the bit line bonding region BLBA and may extend in the direction perpendicular to the top surface of the second substrate 310 to penetrate the word lines 330, the string selection lines, and the ground selection line. The channel structure CH may include a data storage layer, a channel layer, and a filling insulation layer. The channel layer may be electrically connected to a first metal line 350c and a second metal line 360c in the bit line bonding region BLBA. For example, the second metal line 360c may be a bit line and may be connected to the channel structure CH through the first metal line 350c. The bit line 360c may extend in a first direction (e.g., a horizontal direction Y) that may be parallel to the top surface of the second substrate 310.

In some embodiments, as shown in a region A2, the channel structure CH may include a lower channel LCH and an upper channel UCH, which may be connected to each other. For example, the channel structure CH may be formed by a process of forming the lower channel LCH and a process of forming the upper channel UCH. The lower channel LCH may extend in the direction perpendicular to the top surface of the second substrate 310 to penetrate the common source line 320 and lower word lines 331 and 332. The lower channel LCH may include a data storage layer, a channel layer, and a filling insulation layer and may be connected to the upper channel UCH. The upper channel UCH may penetrate upper word lines 333 to 338. The upper channel UCH may include a data storage layer, a channel layer, and a filling insulation layer, and the channel layer of the upper channel UCH may be electrically connected to the first metal line 350c and the second metal line 360c. As a length of a channel increases, due to characteristics of manufacturing processes, it may be difficult to form a channel having a substantially uniform width. In an embodiment, the memory device 500 may include a channel having improved width uniformity due to the lower channel LCH and the upper channel UCH which may be formed by the processes being performed sequentially.

When the channel structure CH includes the lower channel LCH and the upper channel UCH as shown in the region A2, a word line located near to a boundary between the lower channel LCH and the upper channel UCH may be a dummy word line. For example, the word lines 332 and 333 adjacent to the boundary between the lower channel LCH and the upper channel UCH may be the dummy word lines. That is, data may not be stored in memory cells connected to the dummy word line. Alternatively or additionally, the number of pages corresponding to the memory cells connected to the dummy word line may be smaller than the number of pages corresponding to the memory cells connected to a related word line. A voltage level applied to the dummy word line may be different from a voltage level applied to the related word line. Accordingly, it may be possible to reduce an influence of a non-uniform channel width between the lower and upper channels LCH and UCH on an operation of the memory device 500.

In an embodiment, the number of the lower word lines 331 and 332 penetrated by the lower channel LCH may be less than the number of the upper word lines 333 to 338 penetrated by the upper channel UCH in the region A2. However, the present disclosure may not be limited in this regard. For example, in certain embodiments, the number of the lower word lines penetrated by the lower channel LCH may be greater than or equal to the number of the upper word lines penetrated by the upper channel UCH. Alternatively or additionally, structural features and connection relation of the channel structure CH disposed in the second cell region CELL2 may be substantially the same as those of the channel structure CH disposed in the first cell region CELL1.

In the bit line bonding region BLBA, a first through-electrode via (TSV) THV1 may be provided in the first cell region CELL1, and a second TSV THV2 may be provided in the second cell region CELL2. As shown in FIG. 21, the first TSV THV1 may penetrate the common source line 320 and the plurality of word lines 330. In certain embodiments, the first TSV THV1 may further penetrate the second substrate 310. The first TSV THV1 may include a conductive material. Alternatively or additionally, the first TSV THV1 may include a conductive material surrounded by an insulating material. The second TSV THV2 may have a substantially similar shape and/or structure as the first TSV THV1.

In some embodiments, the first TSV THV1 and the second TSV THV2 may be electrically connected to each other through a first through-metal pattern 372d and a second through-metal pattern 472d. The first through-metal pattern 372d may be formed at a bottom end of the first upper chip including the first cell region CELL1, and the second through-metal pattern 472d may be formed at a top end of the second upper chip including the second cell region CELL2. The first TSV THV1 may be electrically connected to the first metal line 350c and the second metal line 360c. A lower via 371d may be formed between the first TSV THV1 and the first through-metal pattern 372d, and an upper via 471d may be formed between the second TSV THV2 and the second through-metal pattern 472d. The first through-metal pattern 372d and the second through-metal pattern 472d may be connected to each other by the bonding method.

Alternatively or additionally, in the bit line bonding region BLBA, an upper metal pattern 252 may be formed in an uppermost metal layer of the peripheral circuit region PERI. An upper metal pattern 392 having a substantially similar shape as the upper metal pattern 252 may be formed in an uppermost metal layer of the first cell region CELL1. The upper metal pattern 392 of the first cell region CELL1 and the upper metal pattern 252 of the peripheral circuit region PERI may be electrically connected to each other by the bonding method. In the bit line bonding region BLBA, the bit line 360c may be electrically connected to a page buffer included in the peripheral circuit region PERI. For example, some of the circuit elements 220c of the peripheral circuit region PERI may constitute the page buffer, and the bit line 360c may be electrically connected to the circuit elements 220c constituting the page buffer through an upper bonding metal pattern 370c of the first cell region CELL1 and an upper bonding metal pattern 270c of the peripheral circuit region PERI.

Continuing to refer to FIG. 21, in the word line bonding region WLBA, the word lines 330 of the first cell region CELL1 may extend in a second direction (e.g., direction X) parallel to the top surface of the second substrate 310. The word lines 330 may be connected to a plurality of cell contact plugs 340 (e.g., 341 to 347). First metal lines 350b and second metal lines 360b may be sequentially connected onto the cell contact plugs 340 connected to the word lines 330. In the word line bonding region WLBA, the cell contact plugs 340 may be connected to the peripheral circuit region PERI through upper bonding metal patterns 370b of the first cell region CELL1 and upper bonding metal patterns 270b of the peripheral circuit region PERI.

The cell contact plugs 340 may be electrically connected to a row decoder included in the peripheral circuit region PERI. For example, some of the circuit elements 220b of the peripheral circuit region PERI may constitute the row decoder, and the cell contact plugs 340 may be electrically connected to the circuit elements 220b constituting the row decoder through the upper bonding metal patterns 370b of the first cell region CELL1 and the upper bonding metal patterns 270b of the peripheral circuit region PERI. In some embodiments, an operating voltage of the circuit elements 220b constituting the row decoder may be different from an operating voltage of the circuit elements 220c constituting the page buffer. For example, the operating voltage of the circuit elements 220c constituting the page buffer may be greater than the operating voltage of the circuit elements 220b constituting the row decoder.

In the word line bonding region WLBA, the word lines 430 of the second cell region CELL2 may extend in the second direction (e.g., direction X) parallel to the top surface of the third substrate 410. The word lines 430 may be connected to a plurality of cell contact plugs 440 (e.g., 441 to 447). The cell contact plugs 440 may be connected to the peripheral circuit region PERI through an upper metal pattern of the second cell region CELL2 and lower and upper metal patterns and a cell contact plug 348 of the first cell region CELL1.

In the word line bonding region WLBA, the upper bonding metal patterns 370b may be formed in the first cell region CELL1. Alternatively or additionally, the upper bonding metal patterns 270b may be formed in the peripheral circuit region PERI. The upper bonding metal patterns 370b of the first cell region CELL1 and the upper bonding metal patterns 270b of the peripheral circuit region PERI may be electrically connected to each other by the bonding method. The upper bonding metal patterns 370b and the upper bonding metal patterns 270b may be formed of a material such as, but not limited to, aluminum (Al), copper (Cu), and/or tungsten (W), and the like.

In the external pad bonding region PA, a lower metal pattern 371e may be formed in a lower portion of the first cell region CELL1, and an upper metal pattern 472a may be formed in an upper portion of the second cell region CELL2. The lower metal pattern 371e of the first cell region CELL1 and the upper metal pattern 472a of the second cell region CELL2 may be connected to each other by the bonding method in the external pad bonding region PA. Alternatively or additionally, an upper metal pattern 372a may be formed in an upper portion of the first cell region CELL1, and an upper metal pattern 272a may be formed in an upper portion of the peripheral circuit region PERI. The upper metal pattern 372a of the first cell region CELL1 and the upper metal pattern 272a of the peripheral circuit region PERI may be connected to each other by the bonding method.

Common source line contact plugs 380 and 480 may be disposed in the external pad bonding region PA. The common source line contact plugs 380 and 480 may be formed of a conductive material such as, but not limited to, a metal, a metal compound, and/or doped polysilicon, and the like. The common source line contact plug 380 of the first cell region CELL1 may be electrically connected to the common source line 320. The common source line contact plug 480 of the second cell region CELL2 may be electrically connected to the common source line 420. A first metal line 350a and a second metal line 360a may be sequentially stacked on the common source line contact plug 380 of the first cell region CELL1. A first metal line 450a and a second metal line 460a may be sequentially stacked on the common source line contact plug 480 of the second cell region CELL2.

Input/output (I/O) pads (e.g., first to third I/O pads 205, 405 and 406) may be disposed in the external pad bonding region PA. Referring to FIG. 21, a lower insulating layer 201 may cover at least a portion of a bottom surface of the first substrate 210, and the first I/O pad 205 may be formed on the lower insulating layer 201. The first I/O pad 205 may be connected to at least one of a plurality of the circuit elements 220a disposed in the peripheral circuit region PERI through a first I/O contact plug 203 and may be separated from the first substrate 210 by the lower insulating layer 201. Alternatively or additionally, a side insulating layer may be disposed between the first I/O contact plug 203 and the first substrate 210 to electrically isolate the first I/O contact plug 203 from the first substrate 210.

An upper insulating layer 401 covering a top surface of the third substrate 410 may be formed on the third substrate 410. A second I/O pad 405 and/or a third I/O pad 406 may be disposed on the upper insulating layer 401. The second I/O pad 405 may be connected to at least one of the plurality of circuit elements 220a disposed in the peripheral circuit region PERI through second I/O contact plugs 403 and 303, and the third I/O pad 406 may be connected to at least one of the plurality of circuit elements 220a disposed in the peripheral circuit region PERI through third I/O contact plugs 404 and 304.

In some embodiments, the third substrate 410 may not be disposed in a region in which the I/O contact plug has been disposed. For example, as shown in a region B, the third I/O contact plug 404 may be separated from the third substrate 410 in a direction parallel to the top surface of the third substrate 410 and may penetrate an interlayer insulating layer 415 of the second cell region CELL2 so as to be connected to the third I/O pad 406. The third I/O contact plug 404 may be formed by at least one of various processes. That is, the present disclosure is not limited in this regard.

In some embodiments, as shown in a region B1, the third I/O contact plug 404 may extend in a third direction (e.g., the vertical direction Z), and a diameter of the third I/O contact plug 404 may become progressively larger (e.g., wider) toward the upper insulating layer 401. That is, a diameter of the channel structure CH described in the region A1 may become progressively smaller (e.g., narrower) toward the upper insulating layer 401, but the diameter of the third I/O contact plug 404 may become progressively larger (e.g., wider) toward the upper insulating layer 401. For example, the third I/O contact plug 404 may be formed after the second cell region CELL2 and the first cell region CELL1 may be bonded to each other by the bonding method.

In certain embodiments, as shown in a region B2, the third I/O contact plug 404 may extend in the third direction (e.g., the vertical direction Z), and a diameter of the third I/O contact plug 404 may become progressively smaller (e.g., narrower) toward the upper insulating layer 401. That is, like the channel structure CH, the diameter of the third I/O contact plug 404 may become progressively smaller (e.g., narrower) toward the upper insulating layer 401. For example, the third I/O contact plug 404 may be formed together with the cell contact plugs 440 before the second cell region CELL2 and the first cell region CELL1 may be bonded to each other.

In certain embodiments, the I/O contact plug may overlap with the third substrate 410. For example, as shown in regions C1, C2, and C3, the second I/O contact plug 403 may penetrate the interlayer insulating layer 415 of the second cell region CELL2 in the third direction (e.g., the vertical direction Z) and may be electrically connected to the second I/O pad 405 through the third substrate 410. A connection structure of the second I/O contact plug 403 and the second I/O pad 405 may be realized by various methods. That is, the present disclosure is not limited in this regard.

In some embodiments, as shown in the region C1, an opening 408 may be formed to penetrate the third substrate 410, and the second I/O contact plug 403 may be connected directly to the second I/O pad 405 through the opening 408 formed in the third substrate 410. That is, as shown in the region C1, a diameter of the second I/O contact plug 403 may become progressively larger (e.g., wider) toward the second I/O pad 405. However, the present disclosure may not be limited in this regard. For example, in certain embodiments, the diameter of the second I/O contact plug 403 may become progressively smaller (e.g., narrower) toward the second I/O pad 405.

In certain embodiments, as shown in the region C2, the opening 408 penetrating the third substrate 410 may be formed, and a contact 407 may be formed in the opening 408. An end of the contact 407 may be connected to the second I/O pad 405, and another end of the contact 407 may be connected to the second I/O contact plug 403. Thus, the second I/O contact plug 403 may be electrically connected to the second I/O pad 405 through the contact 407 in the opening 408. That is, a diameter of the contact 407 may become progressively larger (e.g., wider) toward the second I/O pad 405, and a diameter of the second I/O contact plug 403 may become progressively smaller (e.g., narrower) toward the second I/O pad 405. For example, the second I/O contact plug 403 may be formed together with the cell contact plugs 440 before the second cell region CELL2 and the first cell region CELL1 may be bonded to each other, and the contact 407 may be formed after the second cell region CELL2 and the first cell region CELL1 may be bonded to each other.

In certain embodiments, as shown in the region C3, a stopper 409 may further be formed on a bottom end of the opening 408 of the third substrate 410, as compared with the embodiments of the region C2. The stopper 409 may be a metal line formed in a same layer as the common source line 420. Alternatively or additionally, the stopper 409 may be a metal line formed in a same layer as at least one of the word lines 430. The second I/O contact plug 403 may be electrically connected to the second I/O pad 405 through the contact 407 and the stopper 409.

Similarly to the second and third I/O contact plugs 403 and 404 of the second cell region CELL2, a diameter of each of the second and third I/O contact plugs 303 and 304 of the first cell region CELL1 may become progressively smaller (e.g., narrower) toward the lower metal pattern 371e and/or may become progressively larger (e.g., wider) toward the lower metal pattern 371e.

In some embodiments, a slit 411 may be formed in the third substrate 410. For example, the slit 411 may be formed at a certain position of the external pad bonding region PA. For example, as shown in regions D1, D2, and D3, the slit 411 may be located between the second I/O pad 405 and the cell contact plugs 440 when viewed in a plan view. Alternatively or additionally, the second I/O pad 405 may be located between the slit 411 and the cell contact plugs 440 when viewed in a plan view.

In some embodiments, as shown in the region D1, the slit 411 may be formed to penetrate the third substrate 410. For example, the slit 411 may be used to prevent the third substrate 410 from being finely cracked when the opening 408 is formed. However, the present disclosure may not be limited in this regard. For example, in certain embodiments, the slit 411 may be formed to have a depth ranging from approximately 60% to approximately 70% of a thickness of the third substrate 410.

In certain embodiments, as shown in the region D2, a conductive material 412 may be formed in the slit 411. The conductive material 412 may be used to discharge a leakage current occurring in driving of the circuit elements in the external pad bonding region PA to the outside. That is, the conductive material 412 may be connected to an external ground line.

In certain embodiments, as shown in the region D3, an insulating material 413 may be formed in the slit 411. For example, the insulating material 413 may be used to electrically isolate the second I/O pad 405 and the second I/O contact plug 403 disposed in the external pad bonding region PA from the word line bonding region WLBA. When the insulating material 413 has been formed in the slit 411, it may be possible to prevent a voltage provided through the second I/O pad 405 from affecting a metal layer disposed on the third substrate 410 in the word line bonding region WLBA.

In certain embodiments, the first to third I/O pads 205, 405 and 406 may be selectively formed. For example, the memory device 500 may be realized to include only the first I/O pad 205 disposed on the first substrate 210, to include only the second I/O pad 405 disposed on the third substrate 410, and/or to include only the third I/O pad 406 disposed on the upper insulating layer 401.

In some embodiments, at least one of the second substrate 310 of the first cell region CELL1 and/or the third substrate 410 of the second cell region CELL2 may be used as a sacrificial substrate and may be completely and/or partially removed before and/or after a bonding process. An additional layer may be stacked after the removal of the substrate. For example, the second substrate 310 of the first cell region CELL1 may be removed before and/or after the bonding process of the peripheral circuit region PERI and the first cell region CELL1, and an insulating layer covering a top surface of the common source line 320 and/or a conductive layer for connection may be formed. Similarly, the third substrate 410 of the second cell region CELL2 may be removed before and/or after the bonding process of the first cell region CELL1 and the second cell region CELL2, and the upper insulating layer 401 covering a top surface of the common source line 420 and/or a conductive layer for connection may be formed.

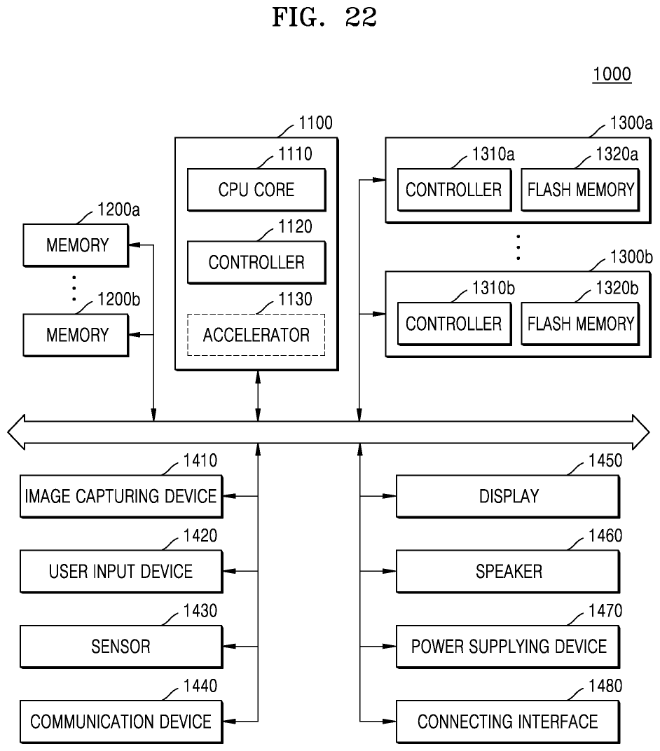

FIG. 22 is a diagram of a system 1000 to which a storage device is applied, according to an embodiment. The system 1000 of FIG. 22 may include, but not be limited to, a mobile system, such as a portable communication terminal (e.g., a mobile phone), a smartphone, a tablet, a personal computer (PC), a wearable device, a healthcare device, an Internet of Things (IoT) device, or the like. However, the system 1000 of FIG. 22 may not be limited to the mobile system and may include another electronic device such as, but not be limited to, a PC, a laptop computer, a server, a media player, an automotive device (e.g., a navigation device), or the like.

Referring to FIG. 22, the system 1000 may include a main processor 1100, memories (e.g., 1200a and 1200b), and storage devices (e.g., 1300a and 1300b). Alternatively or additionally, the system 1000 may include at least one of an image capturing device 1410, a user input device 1420, a sensor 1430, a communication device 1440, a display 1450, a speaker 1460, a power supplying device 1470, and a connecting interface 1480.

The main processor 1100 may control the operations of the system 1000. Alternatively or additionally, the main processor 1100 may control operations of other components included in the system 1000. The main processor 1100 may be implemented as a general-purpose processor, a dedicated processor, and/or an application processor.

The main processor 1100 may include at least one central processing unit (CPU) core 1110, and/or further include a controller 1120 configured to control the memories 1200a and 1200b and/or the storage devices 1300a and 1300b. In some embodiments, the main processor 1100 may further include an accelerator 1130, which may include a dedicated circuit for a high-speed data operation, such as, but not limited to, an artificial intelligence (AI) data operation. For example, the accelerator 1130 may include a graphics processing unit (GPU), a neural processing unit (NPU) and/or a data processing unit (DPU) and/or be implemented as a chip that may be physically separate from the other components of the main processor 1100.

The memories 1200a and 1200b may be used as main memory devices of the system 1000. Each of the memories 1200a and 1200b may include a volatile memory, such as, but not limited to, static random access memory (SRAM) and/or DRAM, and/or a non-volatile memory, such as, but not limited to, a flash memory, PRAM, and/or ReRAM. In some embodiments, the memories 1200a and 1200b may be implemented in the same package as the main processor 1100.

The storage devices 1300a and 1300b may serve as non-volatile storage devices configured to store data regardless of whether power has been supplied thereto, and may have a larger storage capacity than the memories 1200a and 1200b. The storage devices 1300a and 1300b may respectively include storage controllers 1310a and 1310b and flash memories 1320a and 1320b (e.g., non-volatile memories (NVMs)) configured to store data via the control of the storage controllers 1310a and 1310b. Although the flash memories 1320a and 1320b may include flash memories having a 2D structure and/or a 3D (e.g., V-NAND structure), the flash memories 1320a and 1320b may include other types of NVMs, such as, but not limited to, PRAM and/or ReRAM.

The storage devices 1300a and 1300b may be physically separated from the main processor 1100 and be included in the system 1000 and/or implemented in the same package as the main processor 1100. Alternatively or additionally, the storage devices 1300a and 1300b may have types of solid-state devices (SSDs) and/or memory cards and may be removably combined with other components of the system 1000 through an interface, such as the connecting interface 1480 described below. The storage devices 1300a and 1300b may be devices to which a standard protocol, such as a universal flash storage (UFS), an embedded multi-media card (eMMC), or a NVM express (NVMe), may be applied, without being limited in this regard.

The image capturing device 1410 may capture still images and/or moving images. The image capturing device 1410 may include, but not be limited to, a camera, a camcorder, and/or a webcam.

The user input device 1420 may receive various types of data input by a user of the system 1000 and may include, but not be limited to, a touch pad, a keypad, a keyboard, a mouse, and/or a microphone.

The sensor 1430 may detect various types of physical quantities, which may be obtained from the outside of the system 1000, and convert the detected physical quantities into electric signals. The sensor 1430 may include, but not be limited to, a temperature sensor, a pressure sensor, an illuminance sensor, a position sensor, an acceleration sensor, a biosensor, a gyroscope sensor, and/or the like.

The communication device 1440 may transmit and/or receive signals between other devices outside the system 1000, according to various communication protocols. The communication device 1440 may include, but not be limited to, an antenna, a transceiver, a modem, and/or the like.

The display 1450 and the speaker 1460 may serve as output devices configured to output visual information and auditory information, respectively, to the user of the system 1000.

The power supplying device 1470 may convert power supplied from a battery (not shown) embedded in the system 1000 and/or an external power source, and supply the converted power to each of components of the system 1000.

The connecting interface 1480 may provide connections between the system 1000 and external devices, which may be connected to the system 1000 and may be capable of transmitting and/or receiving data to and/or from the system 1000. The connecting interface 1480 may be implemented by using various interface schemes, such as, but not limited to, advanced technology attachment (ATA), serial ATA (SATA), external SATA (e-SATA), small computer small interface (SCSI), serial attached SCSI (SAS), peripheral component interconnection (PCI), PCI express (PCIe), NVMe, Institute of Electrical and Electronics Engineers (IEEE) 1394 (FireWire), a universal serial bus (USB) interface, a secure digital (SD) card interface, a multi-media card (MMC) interface, an eMMC interface, a UFS interface, an embedded UFS (eUFS) interface, a compact flash (CF) card interface, and the like.

While the present disclosure has been particularly shown and described with reference to embodiments thereof, it is to be understood that various changes in form and details may be made therein without departing from the spirit and scope of the following claims.

1. An integrated circuit, comprising:
a substrate; and
a capacitor structure, disposed above the substrate in a vertical direction, comprising:
a first electrode configured to receive a first voltage and comprising at least one first metal line having a first patterned side surface, the at least one first metal line extending in a first horizontal direction;
a second electrode configured to receive a second voltage and comprising at least one second metal line having a second patterned side surface, the at least one second metal line extending in the first horizontal direction; and
a dielectric layer disposed between the first electrode and the second electrode,
the first electrode, the second electrode, and the dielectric layer being disposed on a same layer, and
the at least one second metal line being spaced apart from the at least one first metal line in a second horizontal direction.

2. The integrated circuit of claim 1, wherein a first level of a first upper surface of the at least one first metal line matches a second level of a second upper surface of the at least one second metal line.

3. The integrated circuit of claim 1, wherein:
the first patterned side surface comprises a first pattern extending in the vertical direction,
the second patterned side surface comprises a second pattern extending in the vertical direction,
the first patterned side surface faces the second patterned side surface, and, and
the first pattern and the second pattern have an engagement structure.

4. The integrated circuit of claim 3, wherein:
the first patterned side surface and the second patterned side surface are spaced apart by a first space in the second horizontal direction,
the first metal line has a first width in the second horizontal direction,
the second metal line has a second width in the second horizontal direction, and
the first space comprises at least a portion of the dielectric layer.

5. The integrated circuit of claim 1, wherein:
the first patterned side surface comprises a first saw pattern extending in the vertical direction, and
the second patterned side surface comprises a second saw pattern extending in the vertical direction.

6. The integrated circuit of claim 5, wherein:
the first patterned side surface faces the second patterned side surface,
the first saw pattern of the first patterned side surface has been formed to be engaged with the second saw pattern of the second patterned side surface,
a first height of the first saw pattern matches a second height of the second saw pattern.

7. The integrated circuit of claim 1, wherein:
the first patterned side surface comprises a first polygonal pattern extending in the vertical direction, and
the second patterned side surface comprises a second polygonal pattern extending in the vertical direction.

8. The integrated circuit of claim 7, wherein:
the first patterned side surface faces the second patterned side surface, and
the first polygonal pattern of the first patterned side surface has been formed to be engaged with the second polygonal pattern of the second patterned side surface.

9. The integrated circuit of claim 8, wherein:
the first polygonal pattern comprises a first trapezoidal pattern, and
the second polygonal pattern comprises a second trapezoidal pattern.

10. The integrated circuit of claim 1, wherein:
the first patterned side surface comprises a first semicircular pattern extending in the vertical direction, and
the second patterned side surface comprises a second semicircular pattern extending in the vertical direction.

11. The integrated circuit of claim 10, wherein
the first patterned side surface faces the second patterned side surface, and
the first semicircular pattern of the first patterned side surface has been formed to be engaged with the second semicircular pattern of the second patterned side surface, and
a first diameter of the first semicircular pattern matches a second diameter of the second semicircular pattern.

12. The integrated circuit of claim 1, wherein:
the first patterned side surface comprises at least one of a first semielliptical pattern and a wave pattern extending in the vertical direction, and
the second patterned side surface comprises at least one of a second semielliptical pattern and a second wave pattern extending in the vertical direction.

13. The integrated circuit of claim 12, wherein
the first patterned side surface faces the second patterned side surface, and
the first semielliptical pattern of the first patterned side surface has been formed to be engaged with the second semielliptical pattern of the second patterned side surface, and
a first diameter in a long direction of the first semielliptical pattern matches a second diameter in the long direction of the second semielliptical pattern.

14. The integrated circuit of claim 1, wherein:
the first patterned side surface comprises at least one of a saw pattern, a polygonal pattern, a semicircular pattern, and a semielliptical pattern, and
the second patterned side surface comprises at least one of the saw pattern, the polygonal pattern, the semi-circular pattern, and the semielliptical pattern.

15. The integrated circuit of claim 1, wherein:
the first electrode comprises a plurality of first metal lines comprising the at least one first metal line,
the second electrode comprises a plurality of second metal lines comprising the at least one second metal line, and
the plurality of first metal lines and the plurality of second metal lines are alternately disposed in the second horizontal direction.

16. The integrated circuit of claim 15, wherein:
the first electrode further comprises a first conductive line, extending in the second horizontal direction, coupled to each of the plurality of first metal lines, and
the second electrode further comprises a second conductive line, extending in the second horizontal direction, coupled to each of the plurality of second metal lines.

17. An integrated circuit, comprising:
a substrate; and
a capacitor structure, disposed above the substrate in a vertical direction, comprising:
a first electrode configured to receive a first voltage,
a second electrode configured to receive a second voltage, the first voltage being different from the second voltage, and
a dielectric layer disposed between the first electrode and the second electrode, wherein the first electrode comprises:
a first metal line extending in a first horizontal direction; and
a second metal line extending in the first horizontal direction, disposed above the first metal line in the vertical direction, and coupled to the first metal line, wherein the second electrode comprises:
a third metal line extending in the first horizontal direction, spaced apart from the first metal line in a second horizontal direction, and disposed at a same first level as the first metal line; and
a fourth metal line extending in the first horizontal direction, spaced apart from the second metal line in the second horizontal direction, disposed at a same second level as the second metal line, and coupled to the third metal line, and
wherein side surfaces of each of the first metal line, the second metal line, the third metal line, and the fourth metal line comprise respective patterns extending in the vertical direction.

18-20. (canceled)

21. The integrated circuit of claim 17, wherein:
the first electrode further comprises a plurality of first metal lines disposed at a same first level as the first metal line and a plurality of second metal lines disposed at a same second level as the second metal line,
the second electrode further comprises a plurality of third metal lines disposed at a same third level as the third metal line and a plurality of fourth metal lines disposed at a same fourth level as the fourth metal line,
the plurality of first metal lines and the plurality of third metal lines are alternately disposed in the second horizontal direction, and
the plurality of second metal lines and the plurality of fourth metal lines are alternately disposed in the second horizontal direction.

22. (canceled)

23. A non-volatile memory device, comprising:
a memory cell array comprising a plurality of memory cells respectively coupled to a plurality of word lines; and
a voltage generator comprising a charge pump that comprises at least one capacitor configured to generate voltages applied to the plurality of word lines,
wherein the at least one capacitor comprises a first electrode, a dielectric layer, and a second electrode disposed on a same layer,
wherein the first electrode comprises at least one first metal line having a first patterned side surface, extending in a first horizontal direction, and configured to receive a first voltage, and
wherein the second electrode comprises at least one second metal line having a second patterned side surface, extending in the first horizontal direction, spaced apart from the at least one first metal line in a second horizontal direction, and configured to receive a second voltage, the second voltage being different from the first voltage.

24. The non-volatile memory device of claim 23, wherein
the first patterned side surface comprises a first pattern extending in a vertical direction,
the second patterned side surface comprises a second pattern extending in the vertical direction,
the first patterned side surface faces the second patterned side surface, and
the first pattern and the second pattern have an engagement structure.

25-27. (canceled)
